(19) United States
(12) Patent Application Publication
(10) Pub. No.: US 2025/0248154 A1
(43) Pub. Date: Jul. 31, 2025

(54) SPECTRAL IMAGE SENSOR AND ELECTRONIC DEVICE INCLUDING THE SAME

(71) Applicant: SAMSUNG ELECTRONICS CO., LTD., Suwon-si (KR)

(72) Inventors: Youngho JUNG, Suwon-si (KR); Hyochul KIM, Suwon-si (KR); Younggeun ROH, Suwon-si (KR)

(73) Assignee: SAMSUNG ELECTRONICS CO., LTD., Suwon-si (KR)

(21) Appl. No.: 18/978,697

(22) Filed: Dec. 12, 2024

(30) Foreign Application Priority Data
Jan. 30, 2024 (KR) 10-2024-0001062

(51) Int. Cl. H10F 39/00; H04N 25/11

(52) U.S. Cl. CPC H10F 39/8053; H04N 25/11

(57) ABSTRACT

A spectral image sensor includes a sensor substrate including a plurality of sensing elements, and a spectral filter array on the sensor substrate and including a plurality of spectral filters, each of the plurality of spectral filters configured to transmit light of different center wavelengths, where each of the plurality of spectral filters includes a plurality of unit filters, each of the plurality of unit filters includes a first reflective plate, a second reflective plate, and a resonance layer between the first reflective plate and the second reflective plate, and where the spectral image sensor includes a plurality of partition walls respectively between the plurality of unit filters and configured to optically separate the plurality of unit filters.

### CROSS-REFERENCE TO RELATED APPLICATION

This application is based on and claims priority under 35 U.S.C. § 119 to Korean Patent Application No. 10-2024-0001062, filed on Jan. 3, 2024, in the Korean Intellectual Property Office, the disclosure of which is incorporated by reference herein in its entirety.

### BACKGROUND

### 1. Field

The disclosure relates to a spectral image sensor and an electronic device including the same.

### 2. Description of Related Art

In the case of a related art image sensor, a wavelength band is classified into only three sections: red (R); green (G); and blue (B). However, in order to improve the color representation accuracy and object recognition performance of an image sensor, a spectral image sensor having a spectral filter that divides a wavelength band into more sections is being developed. As related art spectral filters have been used for dedicated cameras consisting of bulky and complex optical element components, the module technology of a spectral image sensor that integrates a spectral filter on a semiconductor chip is still in the research and development stage.

### SUMMARY

Provided are a spectral image sensor and an electronic device including the same.

Additional aspects will be set forth in part in the description which follows and, in part, will be apparent from the description, or may be learned by practice of the presented embodiments of the disclosure.

According to an aspect of the disclosure, a spectral image sensor may include a sensor substrate including a plurality of sensing elements, and a spectral filter array on the sensor substrate and including a plurality of spectral filters, each of the plurality of spectral filters configured to transmit light of different center wavelengths, where each of the plurality of spectral filters may include a plurality of unit filters, each of the plurality of unit filters may include a first reflective plate, a second reflective plate, and a resonance layer between the first reflective plate and the second reflective plate, and where the spectral image sensor may include a plurality of partition walls respectively between the plurality of unit filters and configured to optically separate the plurality of unit filters.

Each of the plurality of partition walls may include a material having a refractive index less than a refractive index of a material of a respective resonance layer.

Each of the plurality of partition walls may include a material having a refractive index in a range of about 1.0 to about 1.1.

Each of the plurality of partition walls may include air or vacuum.

Each of the plurality of partition walls may have a width in a range of about 50 nm to about 100 nm.

Each of the plurality of partition walls may be respectively between each resonance layer.

Each of the plurality of partition walls may respectively extend from a corresponding first reflective plate and a corresponding second reflective plate.

Each of the first reflective plate and the second reflective plate may include a metal reflective layer or a Bragg reflective layer in which at least two dielectrics having different refractive indices are alternately stacked.

Each resonance layer may be configured to have at least one center wavelength in a wavelength band in a range of about 400 nm to about 700 nm.

Each resonance layer may have a thickness in a range of about 100 nm to about 2,000 nm.

Each resonance layer may include a lower resonance layer, an upper resonance layer, and a dielectric separation layer between the lower resonance layer and the upper resonance layer.

The dielectric separation layer may include a material having a refractive index less than or equal to a highest refractive index among a material of the lower resonance layer and a material of the upper resonance layer.

An effective refractive index of the resonance layer of each unit filter of the plurality of unit filters having a same center wavelength may be configured to change based on positions of the unit filters having the same center wavelength, such that the spectral image sensor is configured to compensate for a center wavelength shift caused by a variance in a chief ray angle of incident light.

Each of the plurality of unit filters may have a size in a range of about 0.4 μm to about 100 μm.

The spectral image sensor may include a passivation layer between the sensor substrate and the spectral filter array.

The spectral image sensor may include an additional filter on the plurality of unit filters and configured to transmit light of a specific wavelength band.

The spectral image sensor may include a plurality of microlenses respectively on the plurality of unit filters.

According to an aspect of the disclosure, an electronic device may include a spectral image sensor configured to convert an optical image into an electrical signal, and a processor configured to control the spectral image sensor and output a signal generated by the spectral image sensor, where the spectral image sensor may include a sensor substrate including a plurality of sensing elements and a spectral filter array on the sensor substrate and including a plurality of spectral filters, each of the plurality of spectral filters configured to transmit light of different center wavelengths, where each of the plurality of spectral filters may include a plurality of unit filters, each of the plurality of unit filters may include a first reflective plate, a second reflective plate, and a resonance layer between the first reflective plate and the second reflective plate, and the spectral image sensor may include a plurality of partition walls respectively between the plurality of unit filters and configured to optically separate the plurality of unit filters.

Each of the plurality of partition walls may include a material having a refractive index less than a refractive index of a material of a respective resonance layer.

Each resonance layer may be configured to have at least one center wavelength in a wavelength band in a range of about 400 nm to about 700 nm.

According to an aspect of the disclosure, a spectral image sensor may include a sensor substrate including a plurality of sensing elements and a spectral filter array on the sensor substrate and including a plurality of spectral filters, each of the plurality of spectral filters configured to transmit light of different center wavelengths, where at least one of the plurality of spectral filters includes a first unit filter, a second unit filter adjacent to the first unit filter, and the first unit filter and the second unit filter include a first reflective plate and a second reflective plate, the first unit filter includes a first resonance layer between the first reflective plate and the second reflective plate, the second unit filter includes a second resonance layer between the first reflective plate and the second reflective plate, the second resonance layer configured to have a different center wavelength than a center wavelength of the first resonance layer, and the at least one of the plurality of spectral filters further includes a first partition wall between the first resonance layer and the second resonance layer, the first partition wall being configured to optically separate the first unit filter and the second unit filter.

The first partition wall may extend from a bottom surface of the first reflective plate to a top surface of the second reflective plate.

The first resonance layer may include a first upper resonance layer and a first lower resonance layer, the second resonance layer may include a second upper resonance layer and a second lower resonance layer, and the spectral image sensor may include a dielectric separation layer between the first upper resonance layer and the first lower resonance layer, and between the second upper resonance layer and the second lower resonance layer.

The first partition wall may extend from a bottom surface of the second lower resonance layer to a top surface of the second upper resonance layer.

The at least one of the plurality of spectral filters may include a third unit filter adjacent to the second unit filter and a second partition wall between the second unit filter and the third unit filter, the third unit filter may include a third resonance layer configured to have a different center wavelength different than the center wavelength of the second resonance layer and the center wavelength of the first resonance layer, the third resonance layer may include a third upper resonance layer and a third lower resonance layer, and the second partition wall may extend from a lower surface of the third lower resonance layer to an upper surface of the third upper resonance layer.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a cross-sectional view illustrating a spectral image sensor according to one or more embodiments;

FIG. 2 is a block diagram illustrating a spectral image sensor according to according to one or more embodiments;

FIG. 3 is a plan view illustrating the spectral filter array illustrated in FIG. 2 according to one or more embodiments;

FIG. 4 is a plan view illustrating unit filters applied to the spectral filter shown in FIG. 3 according to one or more embodiments;

FIG. 5 is a cross-sectional view illustrating the spectral filter shown in FIG. 4 according to one or more embodiments;

FIGS. 6A to 6F illustrate patterns that may be applied to a lower/upper resonance layer shown in FIG. 5 according to one or more embodiments;

FIG. 7 is a diagram of graphs illustrating examples of transmission spectra for unit filters of a spectral filter;

FIG. 8 is a diagram of graphs illustrating examples of transmission spectra for unit filters of a spectral filter;

FIG. 9 is a cross-sectional view illustrating a spectral filter according to one or more embodiments;

FIG. 10 is a diagram of graphs illustrating examples of transmission spectra for unit filters of a spectral filter;

FIG. 11 is a cross-sectional view illustrating a spectral filter according to one or more embodiments;

FIG. 12 is a cross-sectional view illustrating a spectral filter according to one or more embodiments;

FIG. 13A is a graph illustrating a transmission spectrum of a spectral filter according to a comparative example;

FIG. 13B is a graph illustrating a transmission spectrum of the spectral filter shown in FIG. 12 according to one or more embodiments;

FIG. 14 is a diagram illustrating a spectral filter according to one or more embodiments;

FIG. 15 is a diagram illustrating a spectral filter according to one or more embodiments;

FIG. 16 is a diagram illustrating a spectral filter according to one or more embodiments;

FIG. 17 is a diagram illustrating a broadband filter that may be used as an additional filter to the spectral filter shown in FIG. 16 according to one or more embodiments;

FIG. 18 is a diagram illustrating a broadband filter that may be used as an additional filter to the spectral filter shown in FIG. 16 according to one or more embodiments;

FIG. 19 is a diagram illustrating a spectral filter array according to one or more embodiments;

FIG. 20 is a diagram illustrating a spectral image sensor according to one or more embodiments;

FIG. 21 is a plan view illustrating unit filters arranged at different positions in the spectral filter array shown in FIG. 20 according to one or more embodiments;

FIG. 22 is a cross-sectional view taken along a line I-I′ of FIG. 21 according to one or more embodiments;

FIG. 23 is a cross-sectional view illustrating a spectral filter according to one or more embodiments;

FIG. 24 is a block diagram illustrating an example of an electronic device according to one or more embodiments;

FIG. 25 is a block diagram illustrating a camera module of FIG. 24 according to one or more embodiments; and

FIGS. 26A to 27E illustrate various examples of an electronic device according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, embodiments will be described in detail with reference to the accompanying drawings. In the following drawings, the same reference numerals refer to the same components, and the size of each component in the drawings may be exaggerated for clarity and convenience of description. Meanwhile, embodiments described below are merely illustrative, and various modifications are possible from these embodiments.

In the following description, when a component is referred to as being “above” or “on” another component, it may be directly on an upper, lower, left, or right side of the other component while making contact with the other component or may be above an upper, lower, left, or right side of the other component without making contact with the other component.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

In addition, terms such as “unit” and “module” described in the specification may indicate a unit that processes at least one function or operation, and this may be implemented as hardware or software, or may be implemented as a combination of hardware and software.

The connection or connection members of lines between the components shown in the drawings exemplarily represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

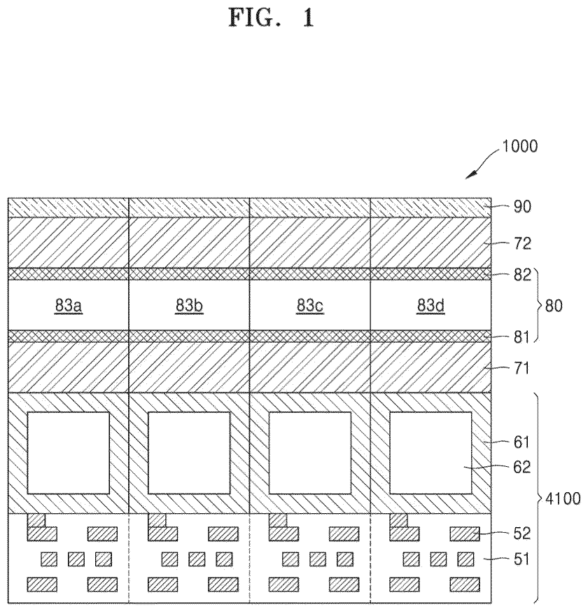

FIG. 1 is a cross-sectional view illustrating a spectral image sensor 1000 according to one or more embodiments. The spectral image sensor 1000 illustrated in FIG. 1 may include, for example, a complementary metal oxide semiconductor (CMOS) image sensor or a charge coupled device (CCD) image sensor.

Referring to FIG. 1, the spectral image sensor 1000 may include a sensor substrate 4100 and a resonator structure 80 provided on the sensor substrate 4100. The sensor substrate 4100 may include a plurality of sensing elements arranged two-dimensionally, and the resonator structure 80 may include a plurality of resonators provided to respectively correspond to the plurality of sensing elements. In FIG. 1, a case where the sensor substrate 4100 includes four sensing elements and the resonator structure 80 includes four resonators is illustrated as an example, and embodiments are not limited thereto.

Each sensing element of the sensor substrate 4100 may include a photodiode 62, which is a photoelectric conversion element, and a driving circuit 52 for driving the photodiode 62. The photodiodes 62 may be embedded in the semiconductor substrate 61. The semiconductor substrate 61 may be, for example, a silicon substrate. However, embodiments are not limited thereto. A wiring layer 51 may be provided on the bottom surface of the semiconductor substrate 61, and the driving circuit 52 such as a metal-oxide-semiconductor (MOS) field effect transistor (FET) (MOSFET) may be provided inside the wiring layer 51.

The resonator structure 80 including a plurality of resonators is provided above the semiconductor substrate 61. Each resonator may be configured to transmit light of a desired specific wavelength band. First and second reflective plates 81 and 82 may be provided to be spaced apart from each other, and resonance layers 83a, 83b, 83c, and 83d may be provided between the first reflective plate 81 and the second reflective plate 82. Each of the first and second reflective plates may include, for example, a metal reflective plate or a Bragg reflective plate. Each of the resonance layers 83a, 83b, 83c, and 83d may be provided to resonate light in a desired specific wavelength band.

A first functional layer 71 may be provided between the top surface of the semiconductor substrate 61 and the resonator structure 80. For example, the first functional layer 71 may serve to improve transmittance of light transmitted through the resonator structure 80 and incident toward the photodiode 62. To this end, the first functional layer 71 may include a dielectric layer or a dielectric pattern having an adjusted refractive index.

A second functional layer 72 may be provided on the top surface of the resonator structure 80. The second functional layer 72 may serve to improve, for example, transmittance of light incident to the resonator structure 80. To this end, the second functional layer 72 may include a dielectric layer or a dielectric pattern having an adjusted refractive index. A third functional layer 90 may be further provided on the top surface of the second functional layer 72. The third functional layer 90 may include, for example, an antireflective layer, a focusing lens, a color filter, a short wavelength absorption filter, a long wavelength blocking filter, or the like. However, this is merely illustrative and embodiments are not limited thereto.

At least one of the first, second, and third functional layers 71, 72, and 90 described above may constitute a spectral filter to be described later together with the resonator structure 80.

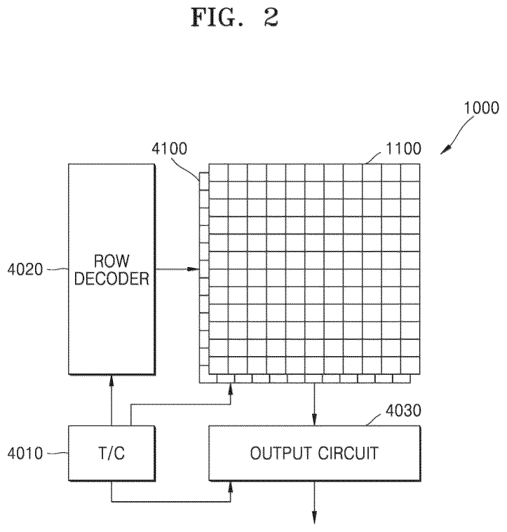

FIG. 2 is a block diagram illustrating a spectral image sensor according to according to one or more embodiments.

Referring to FIG. 2, the spectral image sensor 1000 may include a spectral filter array 1100, a sensor substrate 4100, a timing controller (T/C) 4010, a row decoder 4020, and an output circuit 4030.

As will be described later, the spectral filter array 1100 includes a plurality of spectral filters, and each spectral filter includes a plurality of unit filters that transmit light of different wavelengths. The sensor substrate 4100 includes a plurality of sensing elements for sensing light transmitted through the spectral filter array 1100. Specifically, the sensor substrate 4100 includes sensing elements arranged in two dimensions along a plurality of rows and columns. The row decoder 4020 selects one of rows of the sensor substrate 4100 in response to a row address signal output from the T/C 4010. The output circuit 4030 outputs a light sensing signal in units of columns from a plurality of sensing elements arranged along the selected row. To this end, the output circuit 4030 may include a column decoder and an analog-to-digital converter (ADC). For example, the output circuit 4030 may include a plurality of ADCs arranged for each column between a column decoder and the sensor substrate 4100, or one ADC arranged at the output end of the column decoder. The T/C 4010, the row decoder 4020, and the output circuit 4030 may be implemented as one chip or each separate chip. A processor for processing an image signal output through the output circuit 4030 may be implemented as one chip together with the T/C 4010, the row decoder 4020, and the output circuit 4030.

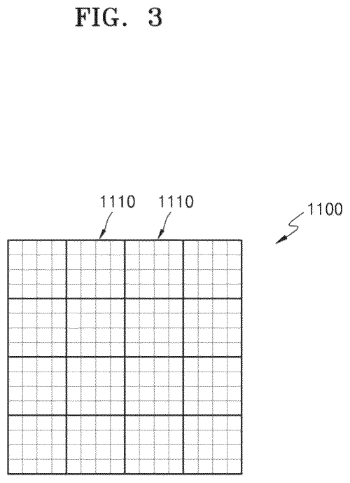

FIG. 3 is a plan view illustrating the spectral filter array 1100 illustrated in FIG. 2 according to one or more embodiments.

Referring to FIG. 3, the spectral filter array 1100 includes a plurality of spectral filters 1110 arranged in a two-dimensional form. In FIG. 3, 16 spectral filters 1110 arranged in the form of a 4×4 array are illustrated as an example, but embodiments are not limited thereto.

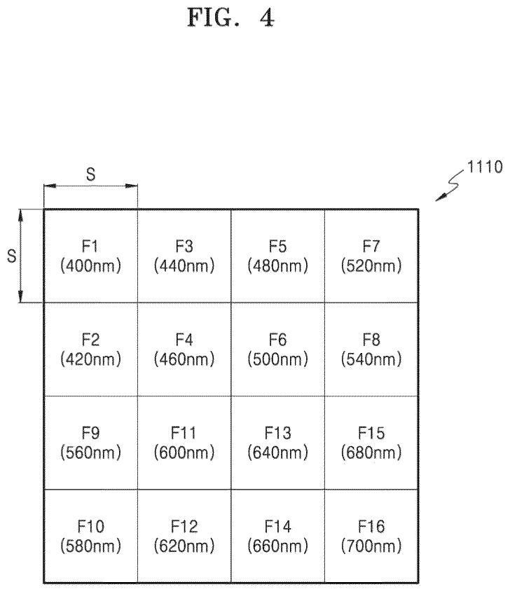

FIG. 4 is a plan view illustrating unit filters applied to the spectral filter 1110 shown in FIG. 3 according to one or more embodiments.

Referring to FIG. 4, the spectral filter 1110 may include a plurality of unit filters F1 to F16 arranged in a two-dimensional form. In FIG. 4, 16 unit filters F1 to F16 constituting the spectral filter 1110 are arranged in the form of a 4×4 array as an example. However, embodiments are not limited thereto and the spectral filter 1110 may be arranged in various forms. For example, the spectral filter 1110 may include nine unit filters arranged in the form of a 3×3 array. The size S (i.e., the length and width) of each of the unit filters F1 to F16 may be, for example, about 0.4 μm to about 100 μm, but is not limited thereto.

Each of the unit filters F1 to F16 constituting the spectral filter 1110 may be configured to have center wavelengths of different bands within a visible light wavelength band (e.g., about 400 nm to about 700 nm band).

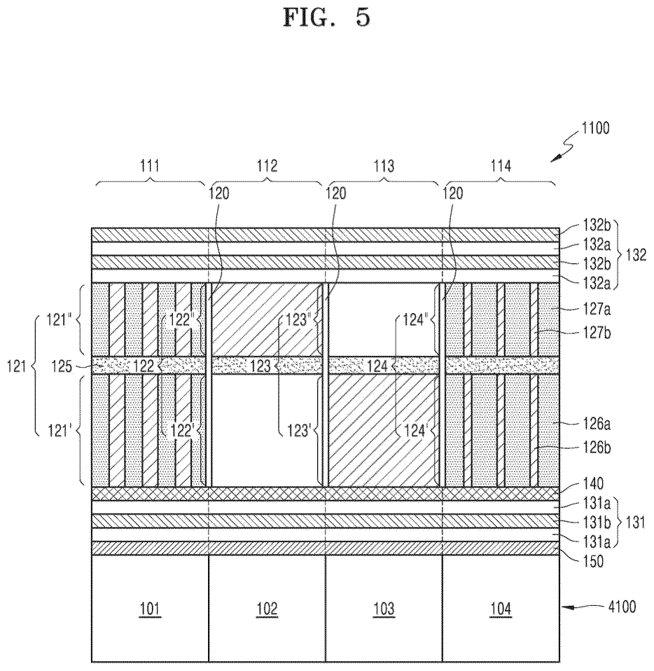

FIG. 5 is a cross-sectional view illustrating the spectral filter 1110 shown in FIG. 4 according to one or more embodiments. For convenience, only four unit filters 111, 112, 113, and 114 are shown in FIG. 5 among the unit filters constituting the spectral filter 1110, which are the same below.

Referring to FIG. 5, the spectral filter 1110 may include a plurality of unit filters 111, 112, 113, and 114. Here, the plurality of unit filters 111, 112, 113, and 114 may be configured to have different center wavelengths within, for example, a band of about 400 nm to about 700 nm. A sensor substrate 4100 including a plurality of sensing elements 101, 102, 103, and 104 corresponding to the plurality of unit filters 111, 112, 113, and 114 may be provided under the spectral filter 1110. In FIG. 5, four unit filters 111, 112, 113, and 114 and four sensing elements 101, 102, 103, and 104 are illustrated as an example. A passivation layer 150 for protecting the sensor substrate 4100 may be additionally provided between the spectral filter 1110 and the sensor substrate 4100. The passivation layer 150 may include, for example, hafnium oxide, silicon oxide, or silicon nitride, but is not limited thereto.

First and second reflective plates 131 and 132 are provided to be spaced apart from each other, such that the first, second, third and fourth unit filters 111, 112, 113 and 114 are between the first and second reflective plates 131 and 132. First, second, third, and fourth resonance layers 121, 122, 123 and 124 are provided between the first and second reflective plates 131 and 132.

Each of the first and second reflective plates 131 and 132 may include a Bragg reflective layer having a structure in which two or more dielectrics having different refractive indices are alternately stacked. In FIG. 5, the first reflective plate 131 includes a Bragg reflective layer in which the first and second dielectrics 131a and 131b are alternately stacked, and the second reflective plate 132 includes a Bragg reflective layer in which the third and fourth dielectrics 132a and 132b are alternately stacked.

First, second, third, and fourth resonance layers 121, 122, 123 and 124 having different center wavelengths are provided between the first and second reflective plates 131 and 132. The resonance layers 121, 122, 123 and 124 may include lower resonance layers 121′, 122′, 123′, and 124′, respectively, and upper resonance layers 121′, 122′, 123′, and 124″, respectively. In addition, the resonance layers 121, 122, 123, and 124 may include a dielectric separation layer 125 provided between the respective lower resonance layers 121′, 122′, 123′, and 124′ and the respective upper resonance layers 121′, 122′, 123″, and 124″.

In other words, the first resonance layer 121 includes a first lower resonance layer 121′, a dielectric separation layer 125, and a first upper resonance layer 121″, and the second resonance layer 122 includes a second lower resonance layer 122′, the dielectric separation layer 125, and a second upper resonance layer 122″. In addition, the third resonance layer 123 includes a third lower resonance layer 123′, the dielectric separation layer 125, and a third upper resonance layer 123″, and the fourth resonance layer 124 includes a fourth lower resonance layer 124′, the dielectric separation layer 125, and a fourth upper resonance layer 124″.

The first, second, third, and fourth lower resonance layers 121′, 122′, 123′, and 124′ may have the same or similar thickness, and the first, second, third, and fourth upper resonance layers 121″, 122″, 123″, and 124″ may have the same or similar thickness. Accordingly, the first, second, third, and fourth resonance layers 121, 122, 123, and 124 may have the same or similar thickness. Each of the first, second, third, and fourth resonance layers 121, 122, 123, and 124 may have a thickness of about 100 nm to about 2000 nm.

The lower resonance layers 121′, 122′, 123′, and 124′ and the upper resonance layers 121″, 122″, 123″, and 124″ respectively constituting the resonance layers 121, 122, 123, and 124 may be configured to have different thicknesses or may be configured to have the same thickness each other. FIG. 5 illustrates a case in which the upper resonance layers 121″, 122″, 123″, and 124″ are configured to have a thickness less than the lower resonance layers 121′, 122′, 123′, and 124′, but embodiments are not limited thereto.

The plurality of resonance layers 121, 122, 123, and 124 may be configured to have different center wavelengths by adjusting thicknesses and effective refractive indices of the lower resonance layers 121′, 122′, 123′, and 124′ and the upper resonance layers 121″, 122″, 123″, and 124″. To this end, each of the lower resonance layers 121′, 122′, 123′, and 124′ and the upper resonance layers 121″, 122″, 123″, and 124″ may include one or more patterns. For example, some of the lower resonance layers 121′, 122′, 123′, and 124′ and the upper resonance layers 121″, 122″, 123″, and 124″ may include one pattern including one dielectric, while others may include multiple patterns including multiple dielectrics having different refractive indices. However, embodiments are not limited thereto, and all of the lower resonance layers 121′, 122′, 123′, and 124′ and the upper resonance layers 121″, 122″, 123″, and 124″ may include multiple patterns including multiple dielectrics having different refractive indices.

Each of the first lower resonance layer 121′ and the first upper resonance layer 121″ constituting the first resonance layer 121 may include a pattern including two dielectrics having different refractive indices. The first lower resonance layer 121′ and the first upper resonance layer 121″ may be configured to have different effective refractive indices or may be configured to have the same effective refractive index each other.

The first lower resonance layer 121′ may include a first dielectric 126a having a relatively low refractive index and a second dielectric 126b having a relatively high refractive index. For example, a dielectric with a relatively low refractive index may include silicon oxide (SiO₂) and a dielectric with a relatively high refractive index may include titanium oxide (TiO₂). However, this is only an example. The effective refractive index of the first lower resonance layer 121′ may be adjusted by changing the volume ratio occupied by the first and second dielectrics 126a and 126b in the first lower resonance layer 121′. For example, as the volume ratio of the second dielectric 126b in the first lower resonance layer 121′ increases, the effective refractive index of the first lower resonance layer 121′ may increase.

The first and second dielectric 126a and 126b constituting the first lower resonance layer 121′ may be arranged in a periodic form or in an aperiodic form to form a pattern.

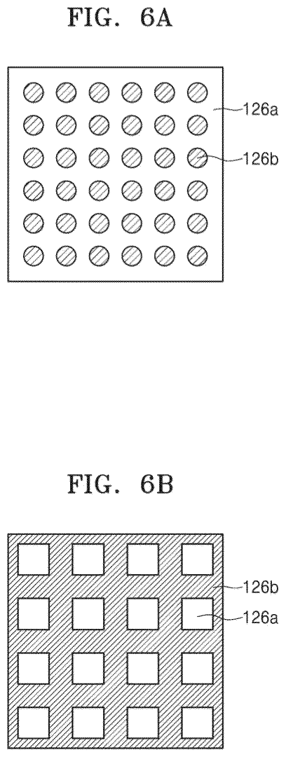

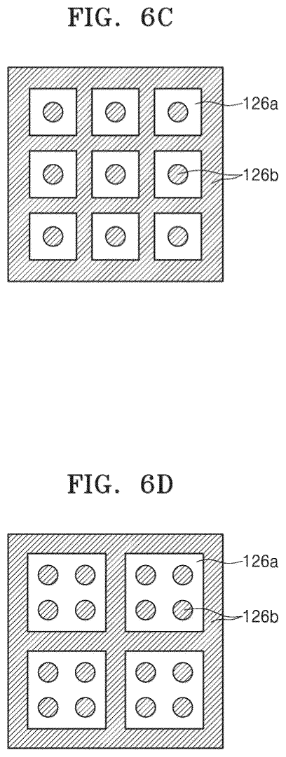

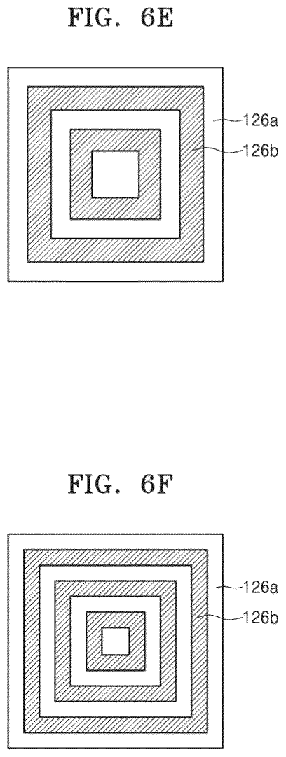

FIGS. 6A to 6F illustrate patterns that may be applied to a lower/upper resonance layer shown in FIG. 5 according to one or more embodiments. FIGS. 6A to 6D illustrate an example in which the first and second dielectrics 126a and 126b are arranged in a periodic form, and FIGS. 6E and 6F illustrate an example in which the first and second dielectrics 126a and 126b are arranged in an aperiodic form.

The first upper resonance layer 121″ may include a third dielectric 127a having a relatively low refractive index and a fourth dielectric 127b having a relatively high refractive index. The effective refractive index of the first upper resonance layer 121″ may be adjusted by changing the volume ratio occupied by the third and fourth dielectrics 127a and 127b in the first upper resonance layer 121″. Like the first lower resonance layer 121′, the third and fourth dielectrics 127a and 127b constituting the first upper resonance layer 121″ may be arranged in a periodic form or in an aperiodic form to form a pattern. FIG. 5 illustrates a case where the first and second dielectrics 126a and 126b constituting the first lower resonance layer 121′ and the third and fourth dielectrics 127a and 127b constituting the first upper resonance layer 121″ are arranged in the same shape.

Each of the second lower resonance layer 122′ and the second upper resonance layer 122″ constituting the second resonance layer 122 may include one dielectric. Specifically, the second lower resonance layer 122′ may include a first dielectric 126a (e.g., silicon oxide) having a relatively low refractive index, and the second upper resonance layer 122″ may include a fourth dielectric 127b (e.g., titanium oxide) having a relatively high refractive index.

Each of the third lower resonance layer 123′ and the third upper resonance layer 123″ constituting the third resonance layer 123 may include one dielectric. Specifically, the third lower resonance layer 123′ may include a second dielectric 126b (e.g., titanium oxide) having a relatively high refractive index, and the third upper resonance layer 123″ may include a third dielectric 127a (e.g., silicon oxide) having a relatively low refractive index.

Each of the fourth lower resonance layer 124′ and the fourth upper resonance layer 124′ constituting the fourth resonance layer 124 may include two dielectrics having different refractive indices, the two dielectrics being arranged in a pattern. The fourth lower resonance layer 124′ and the fourth upper resonance layer 124′ may be configured to have different effective refractive indices or may be configured to have the same effective refractive index each other.

The fourth lower resonance layer 124′ may include a first dielectric 126a having a relatively low refractive index and a second dielectric 126b having a relatively high refractive index. The effective refractive index of the fourth lower resonance layer 124′ may be adjusted by changing the volume ratio occupied by the first and second dielectrics 126a and 126b in the fourth lower resonance layer 124′. The first and second dielectrics 126a and 126b constituting the fourth lower resonance layer 124′ may be arranged in a periodic form or in an aperiodic form.

The fourth upper resonance layer 124″ may include a third dielectric 127a having a relatively low refractive index and a fourth dielectric 127b having a relatively high refractive index. The effective refractive index of the fourth upper resonance layer 124″ may be adjusted by changing the volume ratio occupied by the third and fourth dielectrics 127a and 127b in the fourth upper resonance layer 124″. The third and fourth dielectrics 127a and 127b constituting the fourth upper resonance layer 124″ may be arranged in a periodic form or in an aperiodic form. FIG. 5 illustrates a case where the first and second dielectrics 126a and 126b constituting the fourth lower resonance layer 124′ and the third and fourth dielectrics 127a and 127b constituting the fourth upper resonance layer 124″ are arranged in different shapes.

The dielectric separation layer 125 may be additionally provided between the respective lower resonance layers 121′, 122′, 123′, and 124′ and the respective upper resonance layers 121″, 122″, 123″, and 124″. The dielectric separation layer 125 may include a material having a refractive index less than or equal to a refractive index of a material constituting each of the lower and upper resonance layers 121′, 122′, 123′, 124′, 121″, 122″, 123″, and 124″. Specifically, the dielectric separation layer 125 may include a material having a refractive index equal to or less than the greatest refractive index among the refractive indices of the materials constituting the lower and upper resonance layers 121′, 122′, 123′, 124′, 121″, 122″, 123″, and 124″. For example, the dielectric separation layer 125 may include hafnium oxide (HfO₂) or titanium oxide (TiO₂), but embodiments are not limited thereto.

As a specific example, when the materials constituting the lower and upper resonance layers 121′, 122′, 123′, 124′, 121″, 122″, 123″, and 124″ include silicon oxide and titanium oxide, the dielectric separation layer 125 may include titanium oxide or hafnium oxide.

The dielectric separation layer 125 may be provided between the respective lower resonance layers 121′, 122′, 123′, and 124′ and the respective upper resonance layers 121″, 122″, 123″, and 124″ to perform a function of an etch stop layer. Accordingly, the manufacturing process of the resonance layers 121, 122, 123, and 124 may be facilitated and reproducibility may be improved, and the effective refractive indices of the lower and upper resonance layers 121′, 122′, 123′, 124′ 121″, 122″, 123″, and 124″ may be efficiently adjusted, respectively.

The dielectric separation layer 125 may be formed to have various thicknesses according to process conditions of an etching process. For example, the dielectric separation layer 125 may have a thickness of about 10 nm to about 100 nm, but embodiments are not limited thereto.

The plurality of resonance layers 121, 122, 123, and 124 may be configured to have different center wavelengths in a wavelength band of about 400 nm to about 700 nm by adjusting the effective refractive indices of the lower resonance layers 121′, 122′, 123′, and 124′ and the upper resonance layers 121″, 122″, 123″, and 124″ separated from the dielectric separation layer. Here, each of the resonance layers 121, 122, 123, and 124 may be configured to have one or more center wavelengths in a wavelength band of about 400 nm to about 700 nm.

An etching stop layer 140 may be further provided between the first reflective plate 131 and each of the lower resonance layers 121′, 122′, 123′, and 124′. The etching stop layer 140 may serve to facilitate a patterning process for forming the lower resonance layers 121′, 122′, 123′, and 124′. The etching stop layer 140 may include, for example, titanium oxide or hafnium oxide, but is not limited thereto. For example, the etching stop layer 140 may include a material having an etching rate twice or more (for example, five times or more) slower than a dielectric material constituting the lower resonance layers 121′, 122′, 123′, and 124′. However, embodiments are not limited thereto.

A partition wall 120 may be provided between every two adjacent unit filters among the unit filters 111, 112, 113, and 114. The partition walls 120 may be configured to physically and optically separate the plurality of unit filters 111, 112, 113, and 114 from each other. For example, as shown in FIG. 5, the partition walls 120 may extend from the lower surfaces of the resonance layers 121, 122, 123, and 124 to the upper surfaces of the resonance layers 121, 122, 123, and 124, respectively, and the plurality of unit filters 111, 112, 113, and 114 may be physically and optically separated by the partition walls 120. The partition walls 120 each may have a width of about 50 nm to about 100 nm. The cross-sections of the partition walls 120 may have various shapes. For example, the cross-sections of the partition walls 120 may be rectangular. The partition walls 120 may include a material having a refractive index less than a material forming the resonance layers 121, 122, 123, and 124. Specifically, the partition walls 120 may include a material having a refractive index less than a material having the lowest refractive index among materials forming the resonance layers 121, 122, 123, and 124. The partition walls each may include a material having a refractive index of about 1.0 to about 1.1. For example, the partition walls 120 each may include air. Alternatively, the inside of the partition walls 120 may be in a vacuum state.

In some embodiments, adjacent unit filters 111, 112, 113, and 114 are optically separated from each other by the partition walls 120, thereby effectively reducing crosstalk which may occur between adjacent unit filters 111, 112, 113, and 114. Since the spectral filter array may be monolithically manufactured with the sensor substrate, directization is easy, and the performance of the spectral image sensor may be improved.

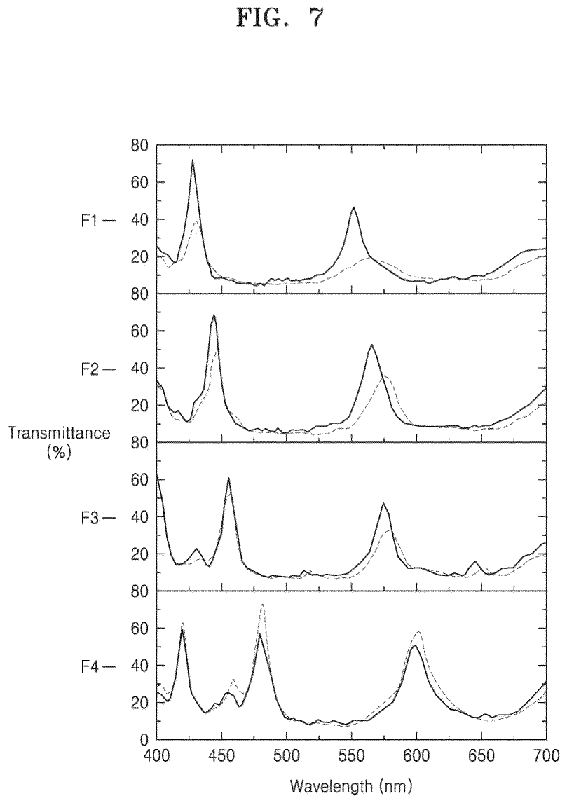

FIG. 7 is a diagram of graphs illustrating examples of transmission spectra for unit filters of a spectral filter. FIG. 7 illustrates examples of comparing transmission spectra for unit filters of a spectral filter 1110 according to one or more embodiments shown in FIG. 5 with transmission spectra for unit filters of a spectral filter according to a comparative example. Here, the spectral filter according to a comparative example refers a case in which there is no partition wall in the spectral filter 1110 illustrated in FIG. 5.

For convenience, transmission spectra for four of the 16 unit filters (F1 to F16) shown in FIG. 4 are shown in FIG. 7. FIG. 7 shows transmission spectra when the size S of each unit filter is set to 1.0 μm. In FIG. 7, a solid line represents a transmission spectrum for unit filters of the spectral filter 1110 including the partition walls 120 according to one or more embodiments, and a dotted line represents a transmission spectrum for unit filters of the spectral filter not including the partition walls according to a comparative example.

Referring to FIG. 7, it may be seen that the unit filters of the spectral filter 1110 including the partition walls 120 have a higher peak height at the central wavelength and a narrower peak width than the unit filters of the spectral filter that do not include the partition walls. As such, in the spectral filter 1110 according to one or more embodiments, crosstalk that may occur between adjacent unit filters may be reduced by providing the partition walls 120 for optical separation between the unit filters.

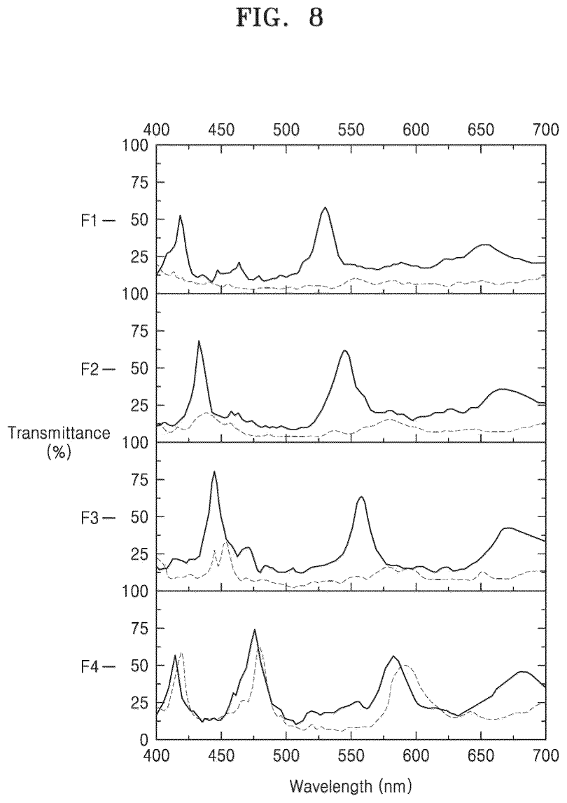

FIG. 8 is a diagram of graphs illustrating examples of transmission spectra for unit filters of a spectral filter. FIG. 8 illustrates examples of comparing transmission spectra for unit filters of a spectral filter 1110 according to one or more embodiments shown in FIG. 5 with transmission spectra for unit filters of a spectral filter according to a comparative example. Here, the spectral filter according to a comparative example refers a case in which there is no partition wall in the spectral filter 1110 illustrated in FIG. 5. FIG. 8 shows transmission spectra when the size S of each unit filter is set to 0.64 μm. In FIG. 8, a solid line represents a transmission spectrum for unit filters of the spectral filter 1110 including the partition walls 120 according to one or more embodiments, and a dotted line represents a transmission spectrum for unit filters of the spectral filter not including the partition walls according to a comparative example.

For convenience, transmission spectra for four of the 16 unit filters (F1 to F16) shown in FIG. 4 are shown in FIG. 8. Referring to FIG. 8, it may be seen that the unit filters of the spectral filter 1110 including the partition wall 120 have a higher peak height at the central wavelength and a narrower peak width than the unit filters of the spectral filter that do not include the partition wall. In addition, compared to the results shown in FIG. 7, it can be seen that as the size of the unit filter decreases from 1.0 μm to 0.64 μm, the unit filters of the spectral filter 110 including the partition wall 120 change the height of the peak and the width of the peak more significantly than the unit filters of the spectral filter that do not include the partition wall. Therefore, as the sizes of the unit filters decrease, crosstalk between adjacent unit filters may be further reduced by providing the partition wall 120 for optical separation between the unit filters.

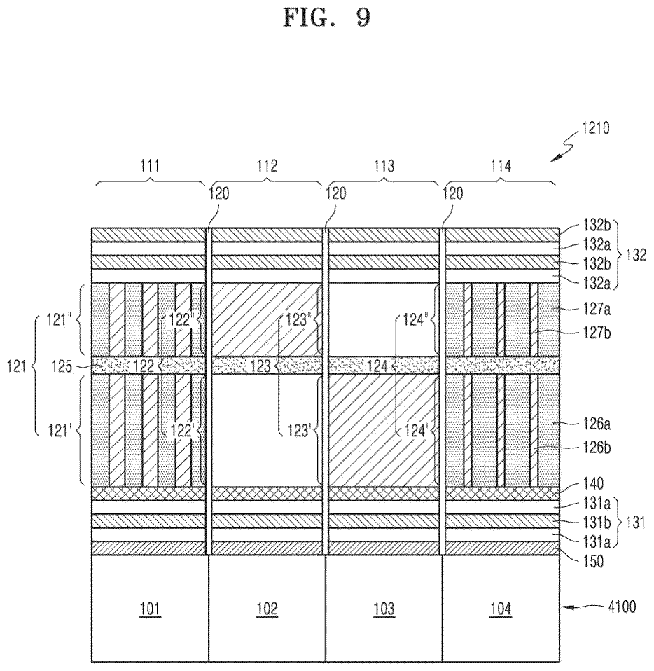

FIG. 9 is a cross-sectional view illustrating a spectral filter according to one or more embodiments. Hereinafter, differences from the embodiments described above are mainly described.

Referring to FIG. 9, a partition wall 120 is provided between every two adjacent unit filters among the unit filters 111, 112, 113, and 114, and the partition wall 120 may extend to the first reflective plate 131 and the second reflective plate 132 between every two adjacent resonance layers among the resonance layers 121, 122, 123, and 124. Specifically, the lower portion of the partition wall 120 may extend to the lower surface of the first reflective plate 131, and the upper portion of the partition wall 120 may extend to the upper surface of the second reflective plate 132. The partition wall 120 may be provided to vertically pass through the first reflective plate 131, each of the resonance layers 121, 122, 123 and 124, and the second reflective plate 132 between every two adjacent unit filters among the unit filters 111, 112, 113, and 114. The unit filters 111, 112, 113, and 114 may be optically separated by the partition walls 120.

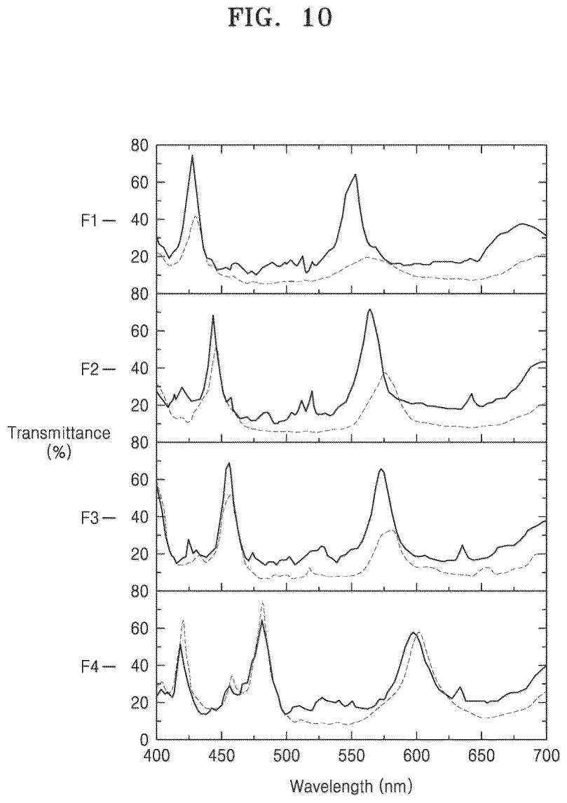

FIG. 10 is a diagram of graphs illustrating examples of transmission spectra for unit filters of a spectral filter. FIG. 10 illustrates examples of comparing transmission spectra for unit filters of a spectral filter 1210 according to one or more embodiments shown in FIG. 9 with transmission spectra for unit filters of a spectral filter according to a comparative example. Here, the spectral filter according to a comparative example refers a case in which there is no partition wall in the spectral filter 1210 illustrated in FIG. 9. For convenience, transmission spectra for four of the 16 unit filters (F1 to F16) shown in FIG. 4 are shown in FIG. 10. FIG. 10 shows transmission spectra when the size S of each unit filter is set to 1.0 μm.

In FIG. 10, a solid line represents a transmission spectrum for unit filters of the spectral filter 1210 including the partition walls 120 according to one or more embodiments, and a dotted line represents a transmission spectrum for unit filters of the spectral filter not including the partition walls according to a comparative example.

Referring to FIG. 10, it may be seen that the unit filters of the spectral filter 1210 including the partition wall 120 have a higher peak height at the central wavelength and a narrower peak width than the unit filters of the spectral filter that do not include the partition wall. In this way, it can be seen that crosstalk decreases between the adjacent unit filters 111, 112, 113, and 114 by providing the partition walls 120 extending to the first and second reflective plates 131 and 132 between two adjacent resonance layers among the resonance layers 121, 122, 123, and 124 of the unit filters 111, 112, 113, and 114.

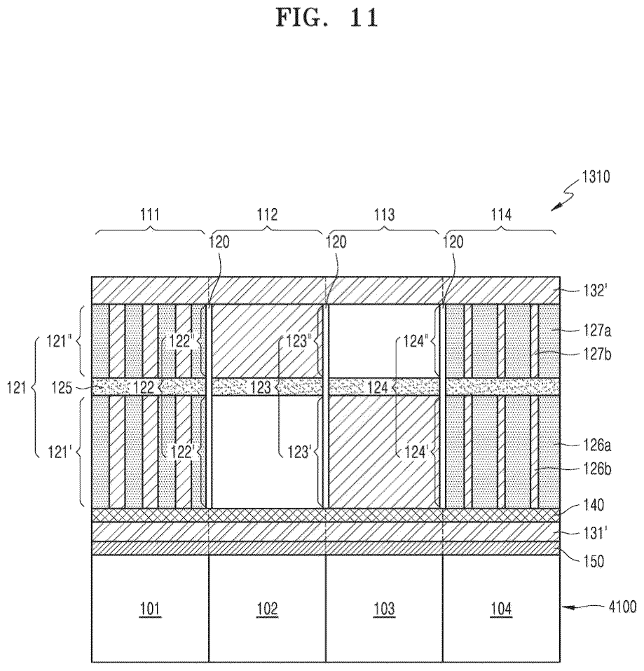

FIG. 11 is a cross-sectional view illustrating a spectral filter according to one or more embodiments. Hereinafter, differences from the embodiments described above are mainly described.

Referring to FIG. 11, first and second reflective plates 131′ and 132′ are provided below and above the resonance layers 121, 122, 123, and 124, respectively. Here, each of the first and second reflecting plates 131′ and 132′ may include a metal reflective plate. The first and second reflective plates 131′ and 132′ may include, for example, Al, Ag, Au, Cu, Ti, W, or TIN, but are not limited thereto.

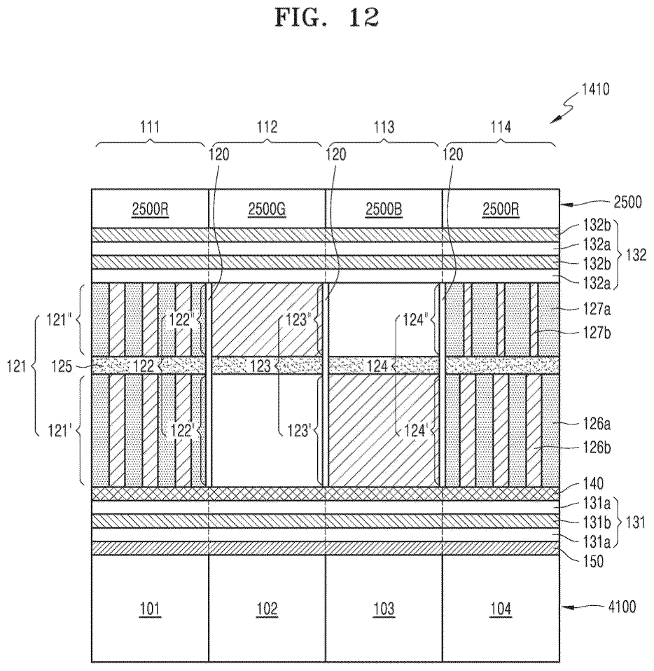

FIG. 12 is a cross-sectional view illustrating a spectral filter according to one or more embodiments. Hereinafter, differences from the embodiments described above are mainly described.

Referring to FIG. 12, a color filter 2500 may be provided in the unit filters 111, 112, 113, and 114. In FIG. 12, the unit filters 111, 112, 113, and 114 are the same as the unit filters 111, 112, 113, and 114 shown in FIG. 5, and the unit filters 111, 112, 113, and 114 may be the unit filters 111, 112, 113, and 114 shown in FIG. 9 or 11.

The color filter 2500 may include, for example, a red filter 2500R, a green filter 2500G, and a blue filter 2500B. As the color filter 2500 including such red, green, and blue filters, for example, a color filter commonly applied to a color display device such as a liquid crystal display device or an organic light emitting display device may be used.

The first color filter 2500R may be provided in the first unit filter 111, the second color filter 2500G may be provided in the second unit filter 112, the third color filter 2500B may be provided in the third unit filter 113, and the fourth color filter 2500R may be provided in the fourth unit filter 114. For example, the first and fourth color filters 2500R and 2500R may be red filters, the second color filter 2500G may be the green filter, and the third color filter 2500B may be the blue filter. Here, the red filter may transmit red light with a wavelength band of about 600 nm to about 700 nm, the green filter may transmit green light with a wavelength band of about 500 nm to about 600 nm, and the blue filter may transmit blue light with a wavelength band of about 400 nm to about 500 nm. Light transmitted through the first color filter 2500R and the first unit filter 111 may have a center wavelength within the red light wavelength band, and light transmitted through the second color filter 2500G and the second unit filter 112 may have a center wavelength within the green light wavelength band. Light transmitted through the third color filter 2500B and the third unit filter 113 may have a center wavelength within the blue light wavelength band, and light transmitted through the fourth color filter 2500R and the fourth unit filter 114 may have a center wavelength within the red light wavelength band.

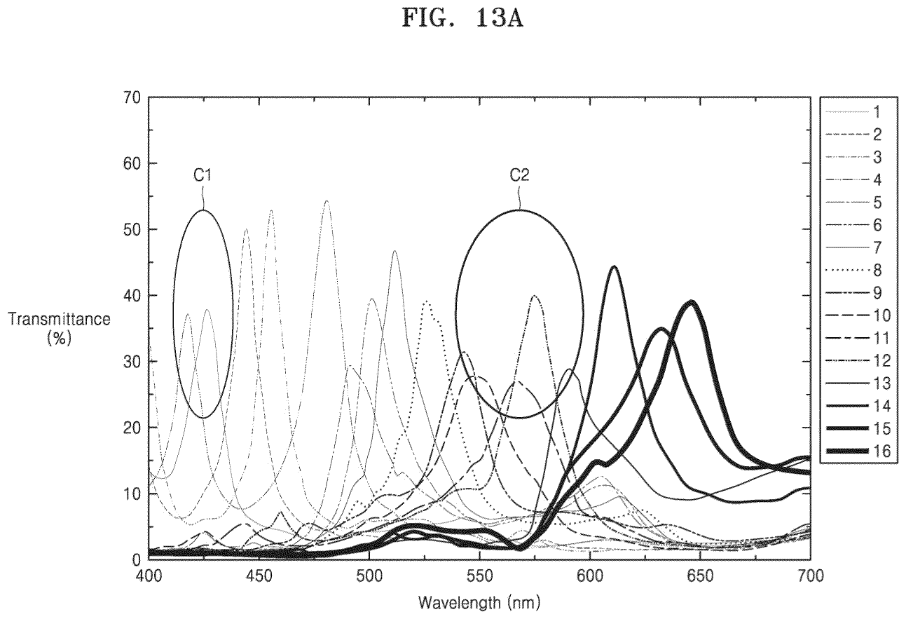

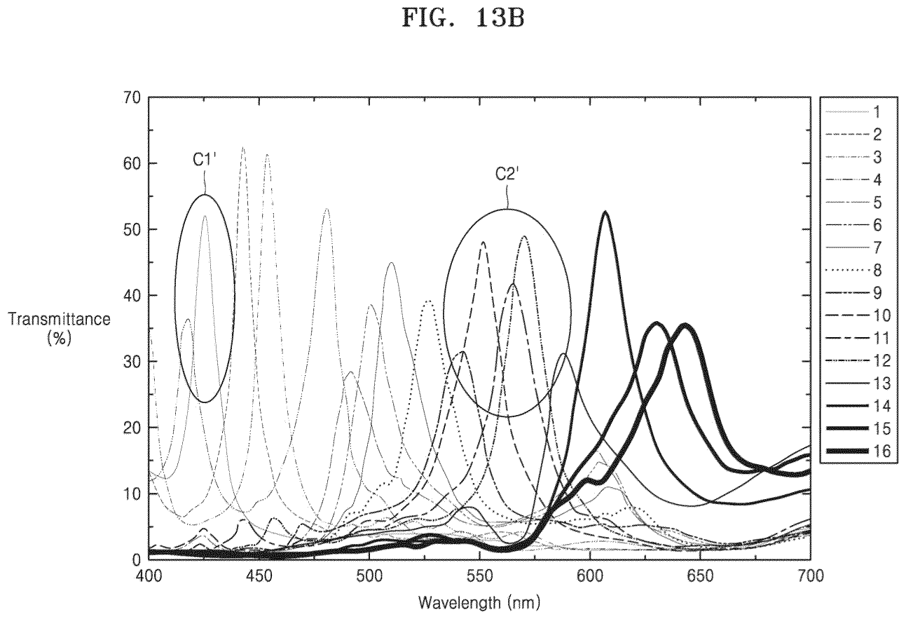

FIG. 13A is a graph illustrating a transmission spectrum of a spectral filter according to a comparative example. FIG. 13B is a graph illustrating a transmission spectrum of the spectral filter 1400 shown in FIG. 12 according to one or more embodiments. Here, the spectral filter according to a comparative example indicates a case in which there is no partition wall in the spectral filter 1410 illustrated in FIG. 12. FIGS. 13A and 13B illustrate a transmission spectrum when a spectral filter includes 16 unit filters having different center wavelengths as an example.

Referring to FIGS. 13A and 13B, it may be seen that the unit filters of the spectral filter 1410 including the partition wall 120 have a higher peak height at the central wavelength and a narrower peak width than the unit filters of the spectral filter that does not include the partition wall. As a specific example, when comparing C1 and C2 regions in the transmission spectrum of the spectral filter not including the partition wall 120 with C1′ and C2′ regions in the transmission spectrum of the spectral filter 1410 including the partition wall 120, it can be seen that the spectral filter 1410 including the partition wall 120 has a significantly higher height of the peak at the central wavelength and a significantly narrower width of the peak compared to the spectral filter that does not include the partition wall.

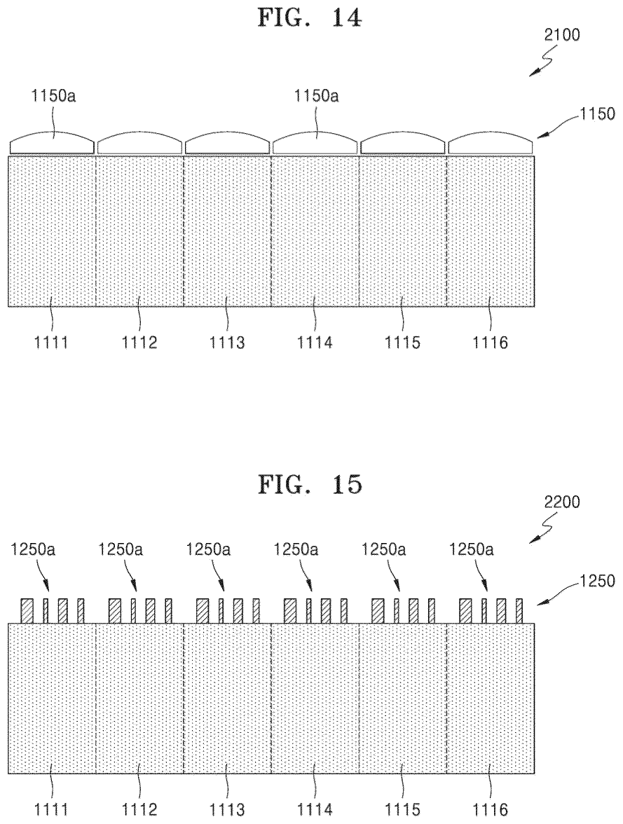

FIG. 14 is a diagram illustrating a spectral filter 2100 according to one or more embodiments.

Referring to FIG. 14, a microlens array 1150 may be provided on an upper portion of a plurality of unit filters 1111 to 1116. The plurality of unit filters 1111 to 1116 may be unit filters described in the embodiments described above, and a partition wall is provided between every two adjacent unit filters among the plurality of unit filters 1111 to 1116. Since the partition wall has been described above, a repeated description thereof may be omitted.

The microlens array 1150 including a plurality of microlenses 1150a may be provided on an upper portion of each of the plurality of unit filters 1111 to 1116. Each microlens 1150a may serve to focus external light to be incident to the corresponding unit filters 1111 to 1116.

FIG. 14 illustrates a case where the microlenses 1150a are provided to correspond one-to-one to the unit filters 1111 to 1116. However, this is only an example, and two or more unit filters 1111 to 1116 may be provided in correspondence to one microlens 1150a.

FIG. 15 is a diagram illustrating a spectral filter 2200 according to one or more embodiments.

Referring to FIG. 15, a nano-pattern array 1250 including a plurality of nano-patterns 1250a may be provided on an upper portion of each of a plurality of unit filters 1111 to 1116. A partition wall may be provided between every two adjacent unit filters among the plurality of unit filters 1111 to 1116. The plurality of nano-patterns 1250a may serve to focus external light to be incident to the corresponding unit filters 1111 to 1116. FIG. 15 illustrates a case where the nano-patterns 1250a are provided to correspond one-to-one to the unit filters 1111 to 1116. However, two or more unit filters 1111 to 1116 may be provided to correspond to one nano-pattern 1250a.

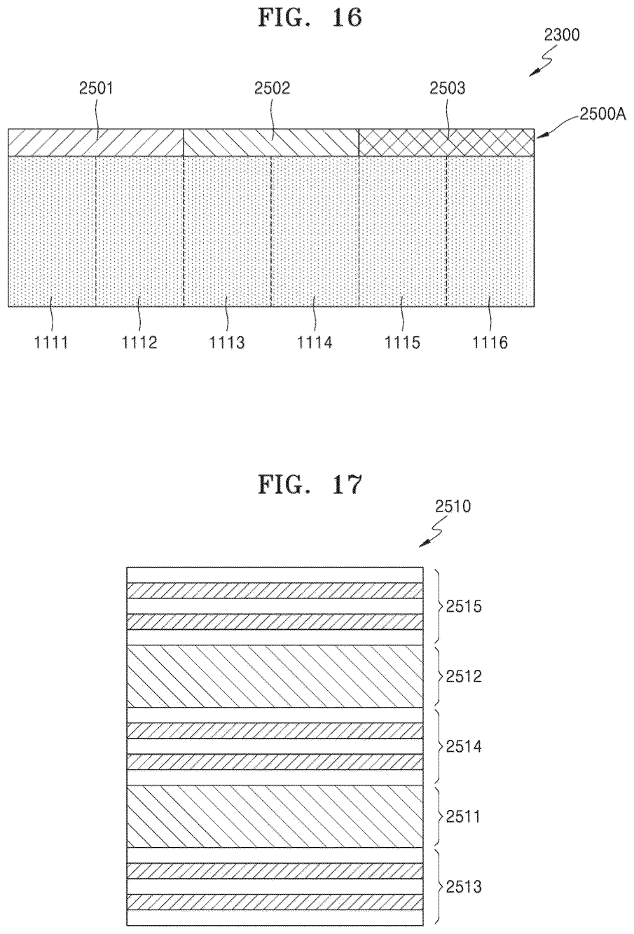

FIG. 16 is a diagram illustrating a spectral filter 2300 according to one or more embodiments.

Referring to FIG. 16, an additional filter array 2500A is provided on a plurality of unit filters 1111 to 1116. A partition wall may be provided between every two adjacent unit filters among the plurality of unit filters 1111 to 1116. The additional filter array 2500A may include a plurality of additional filters 2501, 2502, and 2503. FIG. 16 illustrates a case in which a first additional filter 2501 is provided in correspondence to the first and second unit filters 1111 and 1112, a second additional filter 2502 is provided in correspondence to the third and fourth unit filters 1113 and 1114, and a third additional filter 2503 is provided in correspondence to the fifth and sixth unit filters 1115 and 1116. However, this is only an example, and each of the first, second, and third additional filters 2501, 2502, and 2503 may be provided to correspond to one of the unit filters 1111 to 1116 or to correspond to three or more of the unit filters 1111 to 1116.

The additional filter array 2500A may be a broadband filter array. In this case, the first, second, and third additional filters 2501, 2502, and 2503 may be first, second, and third broadband filters. Here, each of the broadband filters may have, for example, a multi-cavity structure or a metal mirror structure.

FIG. 17 is a diagram illustrating a broadband filter that may be used as an additional filter to the spectral filter shown in FIG. 16 according to one or more embodiments. FIG. 17 illustrates a broadband filter 2510 that may be used as additional filters 2501, 2502, and 2503 shown in FIG. 16.

Referring to FIG. 17, the broadband filter 2510 may include a plurality of reflective plates 2513, 2514, and 2515 spaced apart from each other, and each of a plurality of resonance layers 2511 and 2512 provided between every two adjacent reflective plates among the reflective plates 2513, 2514, and 2515. Three reflective plates 2513, 2514, and 2515 and two resonance layers 2511 and 2512 are illustrated in FIG. 17, but the number of reflective plates 2513, 2514, and 2515 and resonance layers 2511 and 2512 may be variously modified.

Each of the reflective plates 2513, 2514, and 2515 may be a distributed Bragg reflective plate (DBR). Each of the reflective plates 2513, 2514, and 2515 may have a structure in which a plurality of material layers having different refractive indices are alternately stacked. In addition, each of the resonance layers 2511 and 2512 may include a material having a predetermined refractive index or two or more materials having different refractive indices.

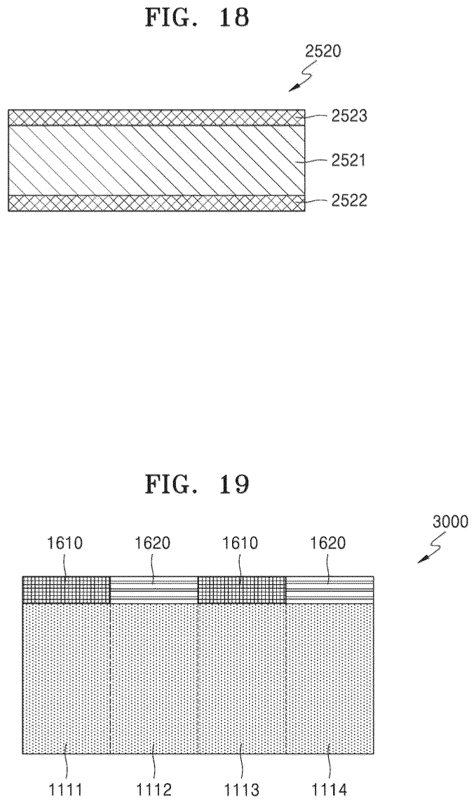

FIG. 18 is a diagram illustrating a broadband filter that may be used as an additional filter to the spectral filter shown in FIG. 16 according to one or more embodiments. FIG. 18 illustrates another broadband filter 2520 that may be used as additional filters 2501, 2502, and 2503 shown in FIG. 16. Referring to FIG. 18, the broadband filter 2520 may include two metal mirror layers 2522 and 2523 spaced apart from each other, and a resonance layer 2521 provided between the metal mirror layers 2522 and 2523.

FIG. 19 is a diagram illustrating a spectral filter array 3000 according to one or more embodiments.

Referring to FIG. 19, at least one short wavelength absorption filter 1610 or at least one long wavelength blocking filter 1620 is provided in each of a plurality of unit filters 1111, 1112, 1113, and 1114. A partition wall may be provided between every two adjacent unit filters among the plurality of unit filters 1111 to 1116. The short wavelength absorption filter 1610 may be provided in some unit filters 1111 and 1113 among the unit filters 1111, 1112, 1113, and 1114, and the long wavelength blocking filter 1620 may be provided in other unit filters 1112 and 1114 among the unit filters 1111, 1112, 1113, and 1114. FIG. 19 shows a case in which each of the short wavelength absorption filter 1610 and the long wavelength blocking filter 1620 corresponds to one of the unit filters 1111, 1112, 1113, and 1114, but is not limited thereto, and each of the short wavelength absorption filter 1610 and the long wavelength blocking filter 1620 may correspond to two or more of the unit filters 1111, 1112, 1113, and 1114.

The short wavelength absorption filter 1610 may serve to block light of a short wavelength such as visible light, for example. The unit filters 1111 and 1113 provided with the short wavelength absorption filter 1610 may transmit near-infrared (NIR) having a wavelength longer than that of visible light. The long wavelength blocking filter 1620 may serve to block light of a long wavelength, such as near infrared rays, for example. The unit filters 1112 and 1114 provided with the long wavelength blocking filter 1620 may transmit visible light having a wavelength shorter than that of near-infrared ray.

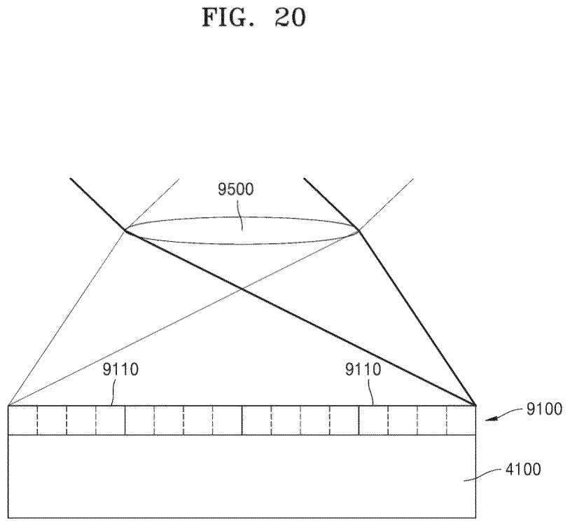

FIG. 20 is a diagram illustrating a spectral image sensor according to one or more embodiments.

Referring to FIG. 20, a spectral filter array 9100 is provided on a sensor substrate 4100, and a single imaging lens 9500 is provided on the upper portion of the spectral filter array 9100. Here, the spectral filter array 9100 may include a plurality of spectral filters 9110. As described above, each spectral filter 9110 may include a plurality of unit filters, and a partition wall may be provided between every two unit filters among the unit filters. In this way, by providing the single imaging lens 9500 for forming an image of an object on the spectral filter array 9100, a camera capable of obtaining a spectral image may be implemented as a simple optical system.

The spectral filter array 9100 may be configured to compensate for a center wavelength shift occurring as the chief ray angle of incident light changes by changing the effective refractive index of the resonance layer according to the position of the unit filter.

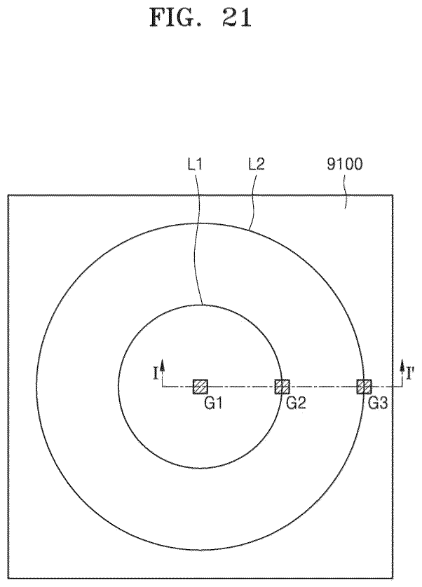

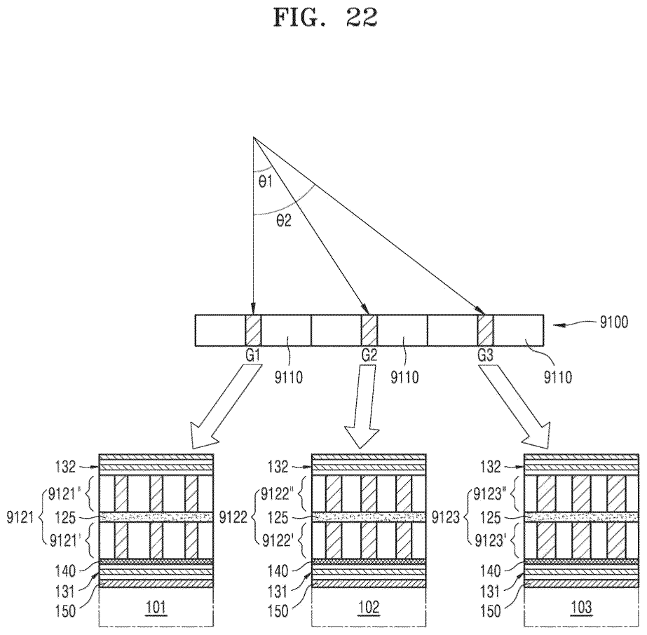

FIG. 21 is a plan view illustrating unit filters G1, G2 and G3 arranged at different positions in the spectral filter array 9100 shown in FIG. 20 according to one or more embodiments. FIG. 22 is a cross-sectional view taken along a line I-I′ of FIG. 21 according to one or more embodiments. Here, among the unit filters of each of the spectral filters 9110 constituting the spectral filter array 9100, G1, G2, and G3 unit filters having the same center wavelength and arranged at different positions are described as an example. A partition wall may be provided between every two adjacent unit filters among a plurality of unit filters constituting each spectral filter 9110.

Referring to FIGS. 21 and 22 together, L1 represents a circle connecting positions where a chief ray angle of incident light is θ1, and L2 represents a circle connecting positions where a chief ray angle of incident light is θ2 (>θ1). The G1 unit filter is located at the center of the spectral filter array 9100, where the chief ray angle of incident light is 0 degrees, the G2 unit filter is located at the position where the chief ray angle of incident light is θ1, and the G3 unit filter is located at the position where the chief ray angle of incident light is θ2. Here, the G1, G2, and G3 unit filters provided at different positions may all have the same center wavelength.

As described above, each of the unit filters G1, G2, and G3 includes first and second reflective plates 131 and 132 provided to be spaced apart from each other, and each of resonance layers 9121, 9122, and 9123 provided between the first and second reflective plates. Here, the resonance layers 9121, 9122, and 9123 may include lower resonance layers 9121′, 9122′, and 9123′, a dielectric separation layer 125, and upper resonance layers 9121″, 9122″, and 9123″, respectively. A partition wall may be provided between every two adjacent unit filters among the unit filters G1, G2, and G3. The first and second reflective plates 131 and 132, the resonance layers 9121, 9122, and 9123, and the partition wall have been described above, and thus a description thereof may be omitted. The sensing elements 101 of the sensor substrate 4100 may be arranged under the first reflective plate 131.

In order to compensate for the center wavelength shift caused by the change in the chief ray angle of incident light, the resonance layers 9121, 9122, and 9123 (more specifically, at least one of the lower and upper resonance layers) may be configured to adjust the effective refractive index according to the positions of the unit filters G1, G2, and G3. Specifically, the effective refractive indices of the resonance layers 9121, 9122, and 9123 may be changed by changing the volume ratio of at least one pattern among the lower and upper resonance layers 9121′, 9122′, 9123′ 9121″, 9122″, and 9123″ according to the positions of the unit filters G1, G2, and G3. Here, the effective refractive indices of the resonance layers 9121, 9122, and 9123 may be adjusted to compensate for a center wavelength shift generated according to a chief ray angle of incident light.

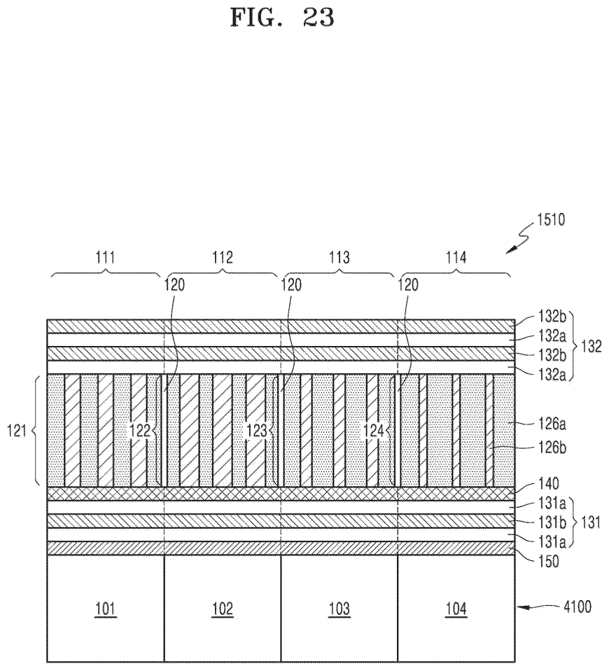

FIG. 23 is a cross-sectional view illustrating a spectral filter according to one or more embodiments.

Referring to FIG. 23, the spectral filter 1510 includes a plurality of unit filters 111, 112, 113, and 114 having different center wavelengths, and a sensor substrate 4100 including a plurality of sensing elements 101, 102, 103, and 104 may be provided below the spectral filter 1510. A passivation layer 150 may be provided between the spectral filter 1510 and the sensor substrate 4100. The spectral filter 1510 differs those previously described in that the dielectric separation layer 125 is not included.

Each unit filter includes first and second reflective plates provided to be spaced apart from each other, and a resonance layer provided between the first and second reflective plates. Each of the first and second reflective plates may be a Bragg reflective layer. The first and second reflective plates may be metal reflective plates.

The first, second, third, and fourth resonance layers 121, 122, 123, and 124 may be provided to have different center wavelengths by adjusting the effective refractive indices. To this end, the first, second, third, and fourth resonance layers 121, 122, 123, and 124 may include different dielectric patterns corresponding to center wavelengths. Each of the resonance layers 121, 122, 123, and 124 may include a first dielectric 126a and a second dielectric 126b periodically arranged in the first dielectric 126a to form a pattern. Here, the second dielectric 126b may have a refractive index different from that of the first dielectric 126a. An etching stop layer 140 may be further provided on lower surfaces of the resonance layers 121, 122, 123, and 124.

A partition wall 120 may be provided between every two adjacent unit filters among the unit filters 111, 112, 113, and 114. The partition walls 120 may be configured to physically and optically separate the plurality of unit filters 111, 112, 113, and 114 from each other. For example, as shown in FIG. 5, the partition walls 120 may extend from the lower parts of the resonance layers 121, 122, 123, and 124 to the upper parts of the resonance layers 121, 122, 123, and 124, respectively, and the plurality of unit filters 111, 112, 113, and 114 may be physically and optically separated by the partition walls 120. The partition walls 120 each may have a width of about 50 nm to about 100 nm. The cross-sections of the partition walls 120 may have various shapes. The partition walls 120 may include a material having a refractive index less than a material forming the resonance layers 121, 122, 123, and 124. Specifically, the partition walls 120 may include a material having a refractive index less than a material having the lowest refractive index among materials forming the resonance layers 121, 122, 123, and 124. The partition walls each may include a material having a refractive index of about 1.0 to 1.1. For example, the partition walls 120 each may include air. Alternatively, the inside of the partition walls 120 may be in a vacuum state. In FIG. 23, a case where the partition walls 120 are formed only in the resonance layers is illustrated, but embodiments are not limited thereto, and the partition walls may be formed to extend to the first and second reflective plates.

As described above, adjacent unit filters 111, 112, 113, and 114 are optically separated from each other by the partition walls 120, thereby effectively reducing crosstalk which may occur between adjacent unit filters 111, 112, 113, and 114.

The spectral image sensors described herein including the spectral filter arrays described herein provided with the partition walls 120 described above may be employed in various high-performance optical devices or high-performance electronic devices. The electronic devices may be, for example, smart phones, mobile phones, portable phones, personal digital assistants (PDAs), laptops, personal computers (PCs), various portable devices, home appliances, security cameras, medical cameras, vehicles, Internet of Things (IoT) devices, other mobile or non-mobile computing devices, and are not limited thereto.

In addition to the spectral image sensor, the electronic device may further include a processor that controls the spectral image sensor, for example, an application processor (AP), and may drive an operating system or application program, through the processor, to control a number of hardware or software components and perform various data processes and operations. The processor may further include a graphical processing unit (GPU) and/or an image signal processor. When an image signal processor is included in the processor, an image (or video) obtained by the spectral image sensor may be stored and/or output using the processor.

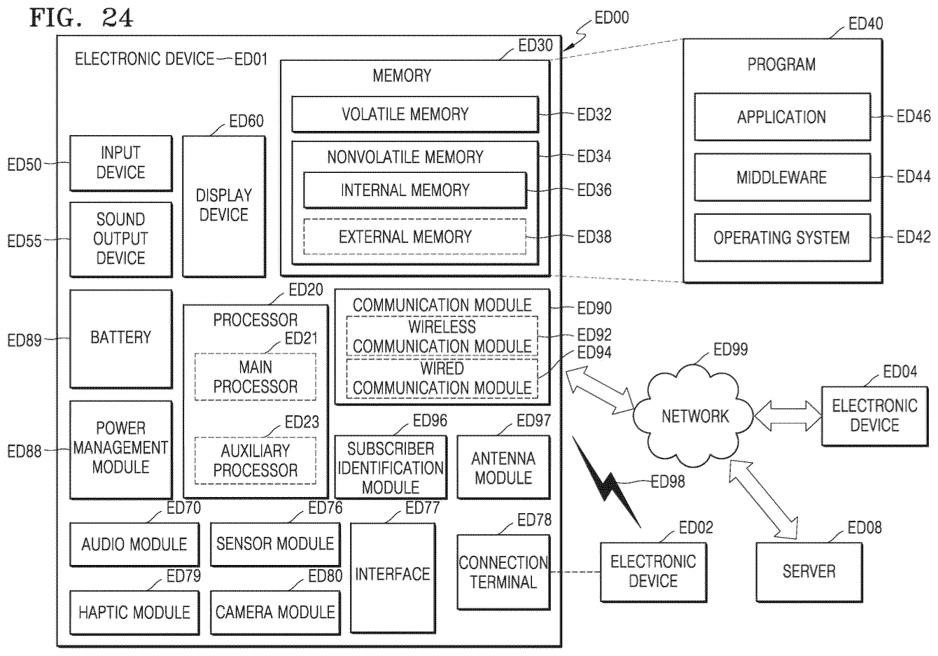

FIG. 24 is a block diagram illustrating an example of an electronic device ED01 according to one or more embodiments. Referring to FIG. 24, under a network environment ED00, the electronic device ED01 may communicate with another electronic device ED02 via a first network ED98 (a short-range wireless communication network, etc.), or may communicate with another electronic device ED04 and/or a server ED08 via a second network ED99 (a long-range wireless communication network, etc.). The electronic device ED01 may communicate with the electronic device ED04 through the server ED08. The electronic device ED01 may include a processor ED20, a memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. Some (the display device ED60, and the like) of these components may be omitted from or other components may be added to the electronic device ED01. Some of these components may be implemented as one integrated circuit. For example, the sensor module ED76 (fingerprint sensor, iris sensor, illuminance sensor, etc.) may be implemented by being embedded in the display device ED60 (display, etc.). In addition, in the case of the spectral image sensor 1000, some functions (color sensor, illuminance sensor) of the sensor module may be implemented in the spectral image sensor 1000 itself, not in a separate sensor module.

The processor ED20 may execute software (program ED40 or the like) to control one or a plurality of other components (hardware, software components, etc.) of the electronic device ED01 connected to the processor ED20, and may perform various data processing or operations. As part of data processing or operation, the processor ED20 may load commands and/or data received from other components (sensor modules ED76, communication modules ED90, etc.), process commands and/or data stored in volatile memory ED32, and store the result data in nonvolatile memory ED34. The processor ED20 may include a main processor ED21 (a central processing unit, an application processor, etc.) and an auxiliary processor ED23 (a graphics processing unit, an image signal processor, a sensor hub processor, a communication processor, etc.) that may be operated independently of or together with the main processor ED21. The auxiliary processor ED23 may use less power than the main processor ED21 and perform a specialized function.

The auxiliary processor ED23 may control the functionality and/or status associated with some of the components of the electronic device ED01 (the display device ED60, the sensor module ED76, the communication module ED90, etc.), in place of the main processor ED21 while the main processor ED21 is in an inactive state (sleep state), or in conjunction with the main processor ED21 while the main processor ED21 is in an active state (application execution state). The auxiliary processor ED23 (image signal processor, communication processor, etc.) may be implemented as part of other functionally related components (camera module ED80, communication module ED90, etc.).

The memory ED30 may store various data required by components (processor ED20 and sensor module ED76) of the electronic device ED01. The data may include, for example, input data and/or output data for software (program ED40 or the like) and related commands. The memory ED30 may include a volatile memory ED32 and/or a nonvolatile memory ED34. The nonvolatile memory ED32 may include an internal memory ED36 fixedly mounted in the electronic device ED01 and a detachable external memory ED38.

The program ED40 may be stored in the memory ED30 as software, and may include an operating system ED42, middleware ED44, and/or an application ED46.

The input device ED50 may receive commands and/or data to be used in components (processor ED20, etc.) of the electronic device ED01 from the outside (user, etc.) of the electronic device ED01. The input device ED50 may include a microphone, a mouse, a keyboard, and/or a digital pen (such as a stylus pen).

The sound output device ED55 may output the sound signal to the outside of the electronic device ED01. The sound output device ED55 may include a speaker and/or a receiver. Speakers may be used for general purposes such as multimedia playback or recording playback, and receivers may be used to receive incoming calls. The receiver may be coupled as part of a speaker or may be implemented as an independent separate device.

The display device ED60 may visually provide information to the outside of the electronic device ED01. The display device ED60 may include a display, a hologram device, or a projector and a control circuit for controlling the corresponding device. The display device ED60 may include a touch circuit configured to sense a touch, and/or a sensor circuit (a pressure sensor, etc.) configured to measure an intensity of a force generated by the touch.

The audio module ED70 may convert sound into an electrical signal or conversely convert the electrical signal into sound. The audio module ED70 may acquire sound through the input device ED50 or output sound through the sound output device ED55 and/or a speaker and/or a headphone of another electronic device (e.g., electronic device ED02, etc.) directly or wirelessly connected to the electronic device ED01.

The sensor module ED76 may detect an operating state (power, temperature, etc.) or an external environmental state (user state, etc.) of the electronic device ED01 and generate an electrical signal and/or a data value corresponding to the sensed state. The sensor module ED76 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illumination sensor.

The interface ED77 may support one or more designated protocols that may be used for electronic device ED01 to be directly or wirelessly connected to another electronic device (e.g., electronic device ED02, etc.). The interface ED77 may include a high definition multimedia interface (HDMI), a universal serial bus (USB) interface, an SD card interface, and/or an audio interface.

The connection terminal ED78 may include a connector through which the electronic device ED01 may be physically connected to another electronic device (e.g., electronic device ED02, etc.). The connection terminal ED78 may include an HDMI connector, a USB connector, an SD card connector, and/or an audio connector (such as a headphone connector, etc.).

The haptic module ED79 may convert an electrical signal to a mechanical stimulus (vibration, motion, etc.) or an electrical stimulus that a user can recognize through a tactile or motion sensation. The haptic module ED79 may include a motor, a piezoelectric element, and/or an electrical stimulus.

The camera module ED80 may capture a still image and a moving image. The camera module ED80 may include a lens assembly including one or more lenses, a spectral image sensor 1000 of FIG. 1, image signal processors, and/or flashes. The lens assembly included in the camera module ED80 may collect light emitted from an object to be photographed.

The power management module ED88 may manage power supplied to the electronic device ED01. The power management module ED88 may be implemented as part of a power management integrated circuit (PMIC).

The battery ED89 may supply power to components of the electronic device ED01. The battery ED89 may include a non-rechargeable primary battery, a rechargeable secondary battery, and/or a fuel cell.

The communication module ED90 may establish a direct (wired) communication channel and/or wireless communication channel between the electronic device ED01 and another electronic device (the electronic device ED02, the electronic device ED04, the server ED08, etc.), and support communication execution through the established communication channel. The communication module ED90 may include one or more communication processors that operate independently of the processor ED20 (AP, etc.) and support direct communication and/or wireless communication. The communication module ED90 may include a wireless communication module ED92 (a cellular communication module, a short-range wireless communication module, a global navigation satellite system (GNSS) communication module, and/or a wired communication module ED94 (a local area network (LAN) communication module, a power line communication module, etc.). A corresponding communication module of these communication modules may communicate with other electronic devices through a first network ED98 (a short-range communication network such as Bluetooth, WiFi Direct, or infrared data association (IrDA)), or a second network ED99 (a long-range communication network such as a cellular network, Internet, or computer network (LAN, wide area network (WAN), etc.)). These various types of communication modules may be integrated into a single component (such as a single chip, etc.), or may be implemented as a plurality of separate components (multiple chips). The wireless communication module ED92 may identify and authenticate the electronic device ED01 in a communication network such as a first network ED98 and/or a second network ED99 using subscriber information (such as an international mobile subscriber identifier (IMSI) stored in the subscriber identification module ED96.

The antenna module ED97 may transmit a signal and/or power to the outside (such as another electronic device, etc.) or receive the signal and/or power from the outside. The antenna may include a radiator formed of a conductive pattern formed on the substrate (printed circuit board (PCB), etc.). The antenna module ED97 may include one or a plurality of antennas. When a plurality of antennas are included, an antenna suitable for a communication scheme used in a communication network such as a first network ED98 and/or a second network ED99 may be selected from among the plurality of antennas by the communication module ED90. A signal and/or power may be transmitted or received between the communication module ED90 and another electronic device through the selected antenna. Other components (radio frequency integrated circuit (RFIC), etc.) in addition to the antenna may be included as a part of the antenna module ED97.

Some of the components may be connected to each other via communication methods between peripherals (such as buses, General Purpose Input and Output (GPIO), Serial Peripheral Interface (SPI), and Mobile Industry Processor Interface (MIPI), etc.) to interchange signals (commands, data, etc.).

The command or data may be transmitted or received between the electronic device ED01 and the external electronic device ED04 through the server ED08 connected to the second network ED99. Other electronic devices ED02 and ED04 may be the same or different types of apparatuses as the electronic device ED01. All or some of the operations executed in the electronic device ED01 may be executed in one or more of the other electronic devices ED02, ED04, and ED08. For example, when the electronic device ED01 needs to perform a function or service, it may request one or more other electronic devices to perform part or all of the function or service instead of executing the function or service on its own. One or more other electronic devices receiving the request may execute an additional function or service related to the request and transmit a result of the execution to the electronic device ED01. To this end, cloud computing, distributed computing, and/or client-server computing technology may be used.

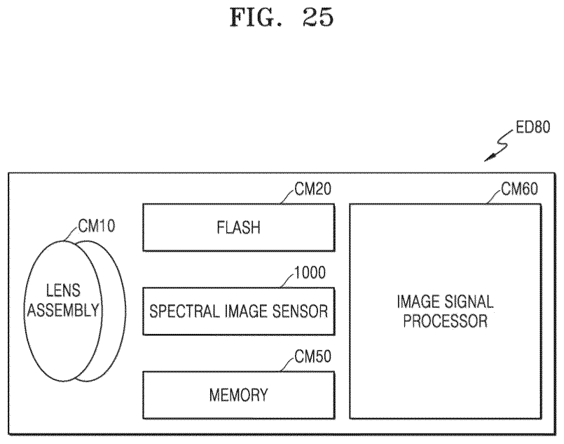

FIG. 25 is a block diagram illustrating the camera module ED80 of FIG. 24 according to one or more embodiments.

Referring to FIG. 25, the camera module ED80 may include a lens assembly CM10, a flash CM20, a spectral image sensor 1000 (such as the spectral image sensor 1000 of FIG. 2), an image stabilizer CM40, a memory CM50 (such as a buffer memory), and/or an image signal processor CM60. The lens assembly CM10 may collect light emitted from a subject to be imaged. The camera module ED80 may include a plurality of lens assemblies CM10, and in this case, the camera module ED80 may be a dual camera, a 360-degree camera, or a spherical camera. Some of the plurality of lens assemblies CM10 may have the same lens properties (view angle, focal length, autofocus, F Number, optical zoom, etc.), or may have different lens properties. The lens assembly CM10 may include a wide-angle lens or a telephoto lens.

The flash CM20 may emit light used to enhance light emitted or reflected from the subject. The flash CM20 may include one or more light emitting diodes (LEDs) (RGB LED, White LED, Infrared LED, Ultraviolet LED, etc.), and/or Xenon Lamps. The spectral image sensor 1000 may be the spectral image sensor described in FIG. 2, and may obtain an image corresponding to an object by converting light emitted or reflected from a subject and transmitted through the lens assembly CM10 into an electrical signal. The spectral image sensor 1000 may include one or a plurality of sensors selected from image sensors having different attributes, such as an RGB sensor or a black and white (BW) sensor. Each of the sensors included in the spectral image sensor 1000 may be implemented as a CCD sensor and/or a CMOS sensor.

In response to the movement of the camera module ED80 or the electronic device CM01 including the same, the image stabilizer CM40 may move the one or more lenses or the spectral image sensor 1000 included in the lens assembly CM10 in a specific direction or control an operation characteristic of the spectral image sensor 1000 to compensate for a negative impact caused by the movement. The image stabilizer CM40 may detect the movement of the camera module ED80 or the electronic device ED01 by using a gyro sensor or an acceleration sensor arranged inside or outside the camera module ED80. The image stabilizer CM40 may be implemented optically.

The memory CM50 may store some or all data of an image acquired through the spectral image sensor 1000 for a next image processing operation. For example, when multiple images are acquired at high speed, the acquired original data (Bayer-Patterned data, high-resolution data, etc.) may be stored in the memory CM50, and used to allow only low-resolution images to displayed, and then the original data of the selected image (user selection, or the like) to be transferred to the image signal processor CM60. The memory CM50 may be integrated into the memory ED30 of the electronic device ED01, or may be configured as a separate memory that operates independently.

The image signal processor CM60 may perform image processes on image obtained through the spectral image sensor 1000 or image data stored in the memory CM50. The image processes may include depth map generation, three-dimensional modeling, panorama generation, feature point extraction, image synthesis, and/or image compensation (noise reduction, resolution adjustment, brightness adjustment, blurring interpolation, sharpening, softening, etc.). The image signal processor CM60 may perform control (exposure time control, read-out timing control, etc.) on components (spectral image sensor 1000, etc.) included in the camera module ED80. The image processed by the image signal processor CM60 may be re-stored in the memory CM50 for further processing or may be provided to an external component of the camera module ED80 (memory ED30, display device ED60, electronic device ED02, electronic device ED04, server ED08, etc.). The image signal processor CM60 may be integrated into the processor ED20 or may be configured as a separate processor that operates independently of the processor ED20. When the image signal processor CM60 is configured as a separate processor from the processor ED20, the image processed by the image signal processor CM60 may be displayed through the display device ED60 after additional image processing by the processor ED20.

The electronic device ED01 may include a plurality of camera modules ED80 having different attributes or functions, respectively. In this case, one of a plurality of camera modules ED80 may be a wide-angle camera, and the other may be a telephoto camera. Similarly, one of a plurality of camera modules ED80 may be a front camera, and the other may be a rear camera.

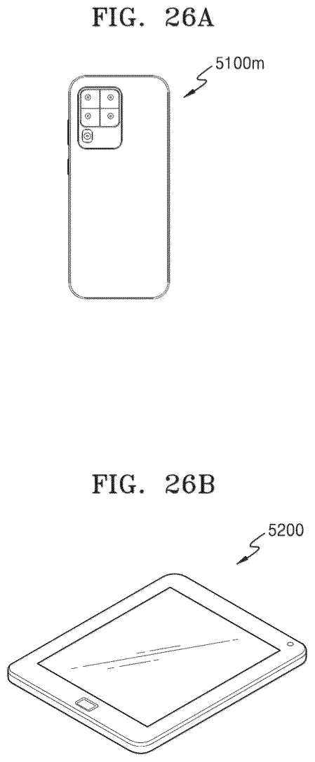

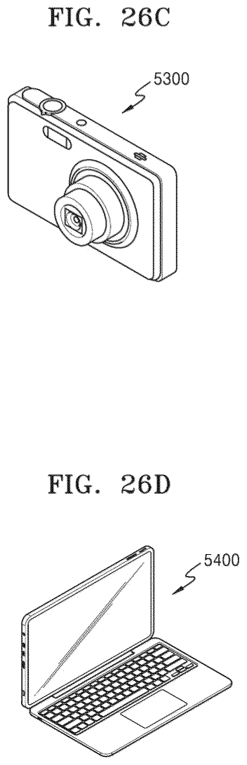

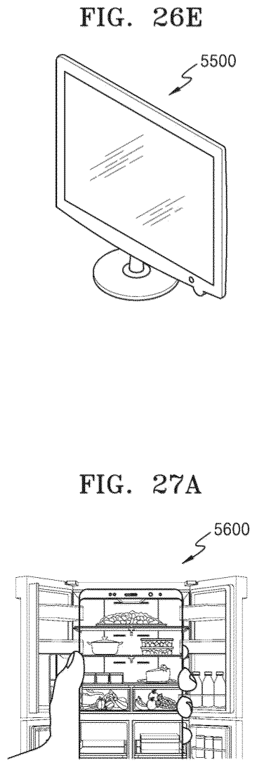

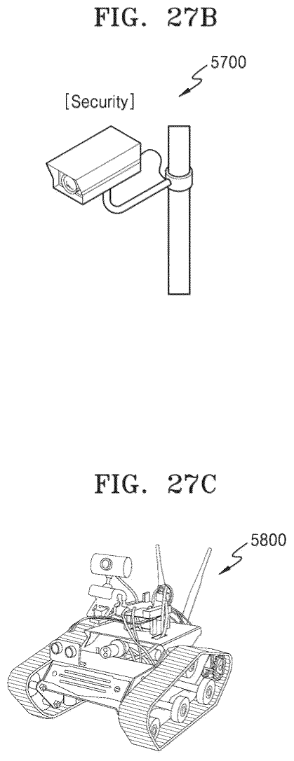

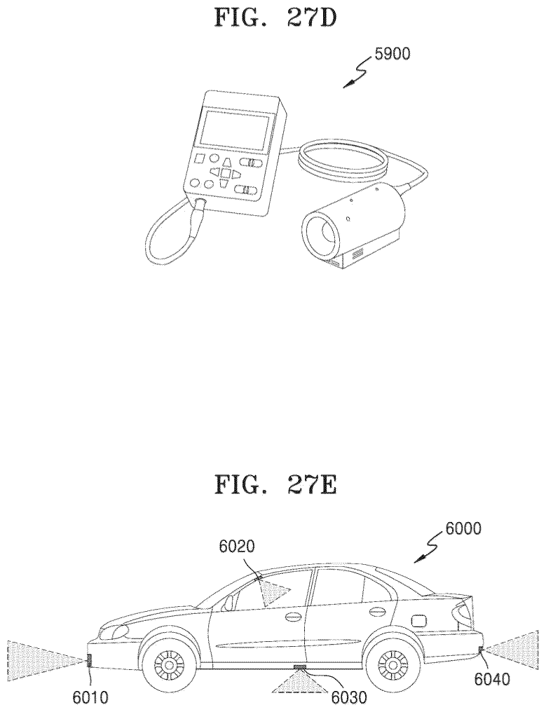

FIGS. 26A to 27E illustrate various examples of an electronic device according to one or more embodiments. The spectral image sensor 1000 according to embodiments may be applied to a mobile phone or smartphone 5100m illustrated in FIG. 26A, a tablet or smart tablet 5200 illustrated in FIG. 26B, a digital camera or camcorder 5300 illustrated in FIG. 26C, a laptop computer 5400 illustrated in FIG. 26D, or a television or smart television 5500 illustrated in FIG. 26E. For example, the smartphone 5100m or the smart tablet 5200 may include a plurality of high-resolution cameras each equipped with a high-resolution spectral image sensor. It is possible to extract depth information of subjects in an image, adjust outfocusing of the image, or automatically identify subjects in the image using high-resolution cameras.

In addition, the spectral image sensor 1000 may be applied to the smart refrigerator 5600 shown in FIG. 27A, the security camera 5700 shown in FIG. 27B, the robot 5800 shown in FIG. 27C, and the medical camera 5900 shown in FIG. 27D. For example, the smart refrigerator 5600 may automatically recognize food in the refrigerator using a spectral image sensor and inform a user of the presence of a specific food, the type of food that is received or released, and the like through a smartphone. The security camera 5700 may provide an ultra-high-resolution image and may enable recognition of objects or people in the image even in a dark environment by using high sensitivity. The robot 5800 may be provided into a disaster or industrial site that is not directly accessible by humans to provide a high-resolution image. The medical camera 5900 may provide a high-resolution image for diagnosis or surgery and may dynamically adjust the field of view.

In addition, the spectral image sensor 1000 may be applied to the vehicle 6000 as illustrated in FIG. 27E. The vehicle 6000 may include a plurality of vehicle cameras 6010, 6020, 6030, and 6040 arranged at various locations. Each of the vehicle cameras 6010, 6020, 6030, and 6040 may include a spectral image sensor according to one or more embodiments. The vehicle 6000 may provide various information about the inside or surrounding of the vehicle 6000 to the driver using a plurality of vehicle cameras 6010, 6020, 6030, and 6040, and may automatically recognize objects or people in the image to provide information necessary for autonomous driving.

The spectral image sensor including a spectral filter array including the partition walls described above and the electronic device including the same have been described with reference to embodiments illustrated in the drawings. According to one or more embodiments, each unit filter of the spectral filter array is optically separated by a partition wall, thereby effectively reducing crosstalk between adjacent unit filters, and facilitating monolithic and directed operation of the spectral image sensor, thereby improving the performance of the spectral image sensor.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A spectral image sensor comprising:
a sensor substrate comprising a plurality of sensing elements; and
a spectral filter array on the sensor substrate and comprising a plurality of spectral filters, each of the plurality of spectral filters configured to transmit light of different center wavelengths,
wherein each of the plurality of spectral filters comprises a plurality of unit filters,
wherein each of the plurality of unit filters comprises a first reflective plate, a second reflective plate, and a resonance layer between the first reflective plate and the second reflective plate; and
wherein the spectral image sensor further comprises a plurality of partition walls respectively between the plurality of unit filters and configured to optically separate the plurality of unit filters.

2. The spectral image sensor of claim 1, wherein each of the plurality of partition walls comprises a material having a refractive index less than a refractive index of a material of a respective resonance layer.

3. The spectral image sensor of claim 1, wherein each of the plurality of partition walls comprises a material having a refractive index in a range of about 1.0 to about 1.1.

4. The spectral image sensor of claim 1, wherein each of the plurality of partition walls comprises air or vacuum.

5. The spectral image sensor of claim 1, wherein each of the plurality of partition walls has a width in a range of about 50 nm to about 100 nm.

6. The spectral image sensor of claim 1, wherein each of the plurality of partition walls is respectively between each resonance layer.

7. The spectral image sensor of claim 6, wherein each of the plurality of partition walls respectively extends from a corresponding first reflective plate and a corresponding second reflective plate.

8. The spectral image sensor of claim 1, wherein each resonance layer is configured to have at least one center wavelength in a wavelength band in a range of about 400 nm to about 700 nm.

9. The spectral image sensor of claim 1, wherein each resonance layer comprises:
a lower resonance layer;
an upper resonance layer; and
a dielectric separation layer between the lower resonance layer and the upper resonance layer.

10. The spectral image sensor of claim 9, wherein the dielectric separation layer comprises a material having a refractive index less than or equal to a highest refractive index among a material of the lower resonance layer and a material of the upper resonance layer.

11. The spectral image sensor of claim 1, wherein an effective refractive index of the resonance layer of each unit filter of the plurality of unit filters having a same center wavelength is configured to change based on positions of the unit filters having the same center wavelength, such that the spectral image sensor is configured to compensate for a center wavelength shift caused by a variance in a chief ray angle of incident light.

12. The spectral image sensor of claim 1, further comprising a passivation layer between the sensor substrate and the spectral filter array.

13. The spectral image sensor of claim 1, further comprising an additional filter on the plurality of unit filters and configured to transmit light of a specific wavelength band.

14. The spectral image sensor of claim 1, further comprising a plurality of microlenses respectively on the plurality of unit filters.

15. An electronic device comprising:
a spectral image sensor configured to convert an optical image into an electrical signal, and
a processor configured to control the spectral image sensor and output a signal generated by the spectral image sensor,
wherein the spectral image sensor comprises:
a sensor substrate comprising a plurality of sensing elements; and
a spectral filter array on the sensor substrate and comprising a plurality of spectral filters, each of the plurality of spectral filters configured to transmit light of different center wavelengths,
wherein each of the plurality of spectral filters comprises a plurality of unit filters,
wherein each of the plurality of unit filters comprises a first reflective plate, a second reflective plate, and a resonance layer between the first reflective plate and the second reflective plate; and
wherein the spectral image sensor further comprises a plurality of partition walls respectively between the plurality of unit filters and configured to optically separate the plurality of unit filters.

16. The electronic device of claim 15, wherein each of the plurality of partition walls comprises a material having a refractive index less than a refractive index of a material of a respective resonance layer.

17. A spectral image sensor, comprising:
a sensor substrate comprising a plurality of sensing elements; and
a spectral filter array on the sensor substrate and comprising a plurality of spectral filters, each of the plurality of spectral filters configured to transmit light of different center wavelengths,
wherein at least one of the plurality of spectral filters comprises a first unit filter, a second unit filter adjacent to the first unit filter,
wherein the first unit filter and the second unit filter comprise a first reflective plate and a second reflective plate,
wherein the first unit filter comprises a first resonance layer between the first reflective plate and the second reflective plate,
wherein the second unit filter comprises a second resonance layer between the first reflective plate and the second reflective plate, the second resonance layer configured to have a different center wavelength than a center wavelength of the first resonance layer, and
wherein the at least one of the plurality of spectral filters further comprises a first partition wall between the first resonance layer and the second resonance layer, the first partition wall being configured to optically separate the first unit filter and the second unit filter.

18. The spectral image sensor of claim 17, wherein the first partition wall extends from a bottom surface of the first reflective plate to a top surface of the second reflective plate.

19. The spectral image sensor of claim 17, wherein the first resonance layer comprises a first upper resonance layer and a first lower resonance layer,
wherein the second resonance layer comprises a second upper resonance layer and a second lower resonance layer, and
wherein the spectral image sensor further comprises a dielectric separation layer between the first upper resonance layer and the first lower resonance layer, and between the second upper resonance layer and the second lower resonance layer.

20. The spectral image sensor of claim 19, wherein the first partition wall extends from a bottom surface of the second lower resonance layer to a top surface of the second upper resonance layer.
